(19) United States
(12) Patent Application Publication
(10) Pub. No.: US 2016/0056611 A1
(43) Pub. Date: Feb. 25, 2016

(54) SEMICONDUCTOR LASER RESONATOR AND SEMICONDUCTOR LASER DEVICE INCLUDING THE SAME

(71) Applicant: SAMSUNG ELECTRONICS CO., LTD., Suwon-si (KR)

(72) Inventors: Chanwook BAIK, Yongin-si (KR); Younggeun ROH, Seoul (KR); Yeonsang PARK, Seoul (KR); Hyochul KIM, Yongin-si (KR)

(73) Assignee: SAMSUNG ELECTRONICS CO., LTD., Suwon-si (KR)

(21) Appl. No.: 14/809,406

(22) Filed: Jul. 27, 2015

(30) Foreign Application Priority Data
Aug. 25, 2014 (KR) 10-2014-0111044
Apr. 6, 2015 (KR) 10-2015-0048324

(51) Int. Cl. H01S 5/10; H01S 5/20; H01S 5/327; H01S 5/343; H01S 5/323

(52) U.S. Cl. CPC H01S 5/10; H01S 5/343; H01S 5/323; H01S 5/327; H01S 5/2054

(57) ABSTRACT

A semiconductor laser resonator configured to generate a laser beam includes a gain medium layer including a semiconductor material and comprising: a central portion; and protrusions periodically arranged around the central portion, one of the protrusions being configured to confine the laser beam as a standing wave in the one protrusion.

### CROSS-REFERENCE TO RELATED APPLICATIONS

This application claims the benefit of Korean Patent Application No. 10-2014-0111044, filed on Aug. 25, 2014, and Korean Patent Application No. 10-2015-0048324, filed on Apr. 6, 2015, in the Korean Intellectual Property Office, the disclosures of which are incorporated herein in their entirety by reference.

### BACKGROUND

1. Field

The exemplary embodiments consistent with the present disclosure relate to a semiconductor laser resonator, and more particularly, to a semiconductor laser resonator capable of selecting or separating a resonant mode from other resonant modes, and a semiconductor laser device including the semiconductor laser resonator.

2. Description of the Related Art

A semiconductor laser resonator is the core component for obtaining an optical gain in a semiconductor laser device. In general, a gain medium of the semiconductor laser resonator has a circular disk shape or a rectangular shape, and a metal or a dielectric material surrounds the gain medium. However, the number of resonant modes generated by such a semiconductor laser resonator is high and the resonant modes are complicated.

### SUMMARY

Provided are semiconductor laser resonators capable of selecting or separating a resonant mode from other resonant modes, and semiconductor laser devices including the semiconductor laser resonators.

Additional aspects will be set forth in part in the description which follows and, in part, will be apparent from the description, or may be learned by practice of the presented exemplary embodiments.

According to an aspect of an example embodiment, a semiconductor laser resonator configured to generate a laser beam includes: a gain medium layer formed of a semiconductor material and including: a central portion; and protrusions periodically arranged around the central portion, wherein one of the protrusions is configured to confine the laser beam as a standing wave in the one protrusion.

The semiconductor laser resonator may further include a metal layer provided outside the gain medium layer, the metal layer being configured to confine a laser beam generated by the gain medium layer.

The semiconductor laser resonator may further include a buffer layer provided between the gain medium layer and the metal layer, the buffer layer being configured to buffer an optical loss of the laser beam generated by the gain medium layer.

The semiconductor laser resonator may further include a dielectric layer provided outside the gain medium layer, the dielectric layer being configured to confine the laser beam generated by the gain medium layer, and having a refractive index different from a refractive index of the gain medium layer.

The central portion may be configured to further confine the laser beam therein.

The protrusions may have a same shape as each other.

The protrusions may include a first protrusions each respectively having a first shape and f second protrusions each respectively having a second shape different from the first shape.

The first and second protrusions may be alternately arranged around the central portion.

The central portion may have a circular or quadrangular plane shape.

The semiconductor laser resonator may further include a through hole formed in the central portion.

The semiconductor laser resonator may further include recessed portions formed between the protrusions at regular intervals from each other.

The recessed portions may be formed only at a part of the gain medium layer along a thickness direction of the gain medium layer.

A number of the protrusions may be from 2 to 10, and an angle between two sides of one of the protrusions, the two sides extending from a center of the gain medium layer to an outer circumference of the gain medium layer, may be from 5° to 175°.

A thickness of the gain medium layer may be less than or equal to 500 nm, an outer radius of the gain medium layer extending from the center of the gain medium layer to the outer circumference of the gain medium layer may be from 100 nm to 5,000 nm, an inner radius of the gain medium layer extending from the center of the gain medium layer to an inner side of the recessed portions may be from 100 nm to 4,000 nm, and a ratio of the inner radius to the outer radius may be from 0.02 to 1.

The gain medium layer may include an active layer.

The active layer may include at least one of a III-V group semiconductor material, a II-VI group semiconductor material, and quantum dots.

The gain medium layer may further include: a first clad layer provided on a first surface of the active layer; and a second clad layer provided on a second surface of the active layer.

The semiconductor laser resonator may further include: a first contact layer provided on a first surface of the gain medium layer; and a second contact layer provided on a second surface of the gain medium layer.

The first contact layer and the second contact layer may have a shape corresponding to a shape of the gain medium layer.

According to another aspect of another exemplary embodiment, a semiconductor laser device includes: a substrate; and a semiconductor laser resonator provided on the substrate and configured to generate a laser beam by absorbing energy, the semiconductor laser resonator includes a gain medium layer including a semiconductor material and further including: a central portion; and protrusions periodically arranged around the central portion, wherein one of the protrusions is configured to confine a standing wave in the one protrusion.

The semiconductor laser device may further include a metal layer provided outside the gain medium layer, the metal layer being configured to confine the laser beam generated by the gain medium layer.

The semiconductor laser device may further include a buffer layer provided between the gain medium layer and the metal layer, the buffer layer being configured to buffer an optical loss of the laser beam generated by the gain medium layer.

The semiconductor laser device may further include a dielectric layer provided outside the gain medium layer, the dielectric layer being configured to confine the laser beam generated by the gain medium layer, and having a refractive index different from the gain medium layer.

The central portion may have a circular or quadrangular plane shape.

The semiconductor laser device may further include a through hole in the central portion.

The semiconductor laser device may further include recessed portions formed between the protrusions at regular intervals from each other.

The recessed portions may be formed only at a part of the gain medium layer along a thickness direction of the gain medium layer.

The semiconductor laser device may further include: a first contact layer provided on a first surface of the gain medium layer; and a second contact layer provided on a second surface of the gain medium layer.

The semiconductor laser device may further include electrodes electrically connected to the first contact layer and the second contact layer.

### BRIEF DESCRIPTION OF THE DRAWINGS

The patent or application file contains at least one drawing executed in color. Copies of this patent or patent application publication with color drawings(s) will be provided by the Office upon request and payment of the necessary fee.

These and/or other aspects will become apparent and more readily appreciated from the following description of the exemplary embodiments, taken in conjunction with the accompanying drawings in which:

FIG. 1 is a perspective view of a semiconductor laser device according to an exemplary embodiment;

FIG. 2 is a partially cutaway perspective view of the semiconductor laser device of FIG. 1;

FIG. 3 is a cross-sectional view of the semiconductor laser device of FIG. 1;

FIGS. 4A and 4B are respectively a perspective view and a plan view of a gain medium layer of a semiconductor device, according to an exemplary embodiment;

FIG. 5 is a cross-sectional view of a semiconductor laser device according to another exemplary embodiment;

FIG. 6 is a plan view and a perspective view of a general cylindrical gain medium layer;

FIG. 7 illustrates a spectrum of a laser beam generated by the gain medium layer of FIG. 6;

FIGS. 8A, 8B, 8C, 8D, 8E, 8F and 8G illustrate intensity distributions of an electric field of the laser beam generated by the gain medium layer of FIG. 6;

FIG. 9 illustrates a spectrum of a laser beam generated by the gain medium layer of FIGS. 4A and 4B;

FIGS. 10A, 10B, 10C and 10D illustrate intensity distributions of an electric field of the laser beam generated by the gain medium layer of FIGS. 4A and 4B;

FIG. 11 is a diagram for describing a relationship between wavelengths and a ratio of an inner radius to an outer radius of the gain medium layer of FIGS. 4A and 4B;

FIGS. 12A and 12B are respectively a perspective view and a plan view of a gain medium layer according to another exemplary embodiment;

FIG. 13 illustrates a spectrum of a laser beam generated by the gain medium layer of FIGS. 12A and 12B;

FIGS. 14A and 14B illustrate intensity distributions of an electric field of the laser beam generated by the gain medium layer of FIGS. 12A and 12B;

FIG. 15 is a diagram for describing a relationship between wavelengths and a ratio of an outer radius to an inner radius of the gain medium layer of FIGS. 12A and 12B;

FIG. 16A is a view of the gain medium layer of FIGS. 12A and 12B, wherein silver (Ag) surrounds the gain medium layer and silicon oxide (SiO₂) covers an upper portion of the gain medium layer;

FIGS. 16B, 16C, 16D and 16E illustrate intensity distributions of an electric field of a TE₂₁ mode laser beam generated by the gain medium layer of FIG. 16A;

FIG. 16F illustrates a spectrum of the TE₂₁ mode laser beam generated by the gain medium layer of FIG. 16A;

FIG. 17 is a perspective view of a gain medium layer according to another exemplary embodiment;

FIG. 18 is a perspective view of a gain medium layer according to another exemplary embodiment;

FIG. 19 is a perspective view of a gain medium layer according to another exemplary embodiment;

FIGS. 20A, 20B, 20C and 20D are perspective views of gain medium layers according to other exemplary embodiments;

FIGS. 21A and 21B are respectively a perspective view and a plan view of a gain medium layer according to another exemplary embodiment;

FIG. 21C illustrates intensity distributions of an electric field of a laser beam generated by the gain medium layer of FIGS. 21A and 21B;

FIGS. 22A, 22B, 22C and 22D illustrate gain medium layers according to other exemplary embodiments;

FIGS. 23A, 23B, 23C, 23D, 23E and 23F illustrate gain medium layers according to other exemplary embodiments;

FIGS. 24A and 24B illustrate gain medium layers according to other exemplary embodiments;

FIGS. 25A and 25B illustrate gain medium layers according to other exemplary embodiments; and

FIG. 26 illustrates intensity distributions of an electric field of a laser beam generated by the gain medium layer of FIG. 25A.

### DETAILED DESCRIPTION

Reference will now be made in detail to exemplary embodiments, examples of which are illustrated in the accompanying drawings, wherein like reference numerals refer to like elements throughout and thicknesses or sizes of elements may be exaggerated for clarity. When a certain material layer is disposed on a substrate or a layer, the certain material layer may be directly disposed on the substrate or the layer, or an intervening layer may be disposed therebetween. Also, since a material forming each layer is only an example, another material may be used to form the each layer. As used herein, the term “and/or” includes any and all combinations of one or more of the associated listed items. Expressions such as “at least one of,” when preceding a list of elements, modify the entire list of elements and do not modify the individual elements of the list.

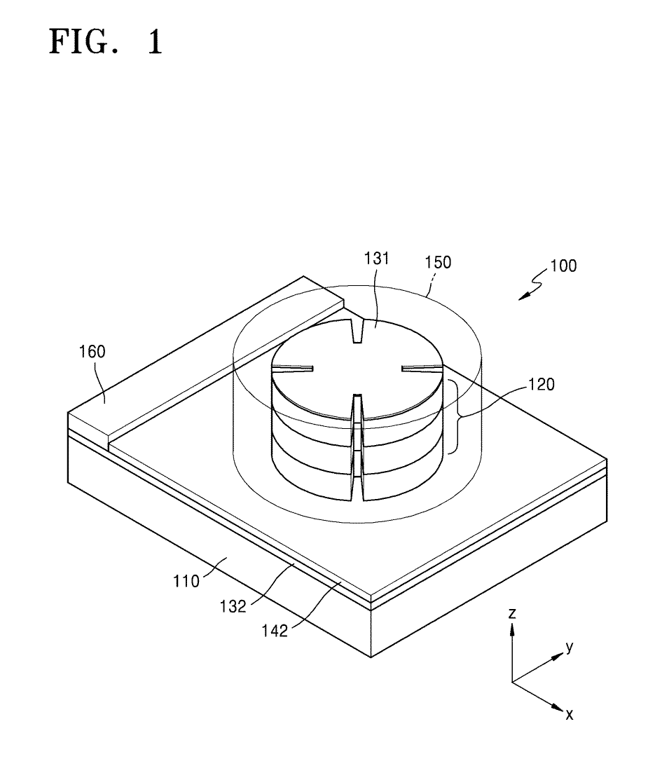

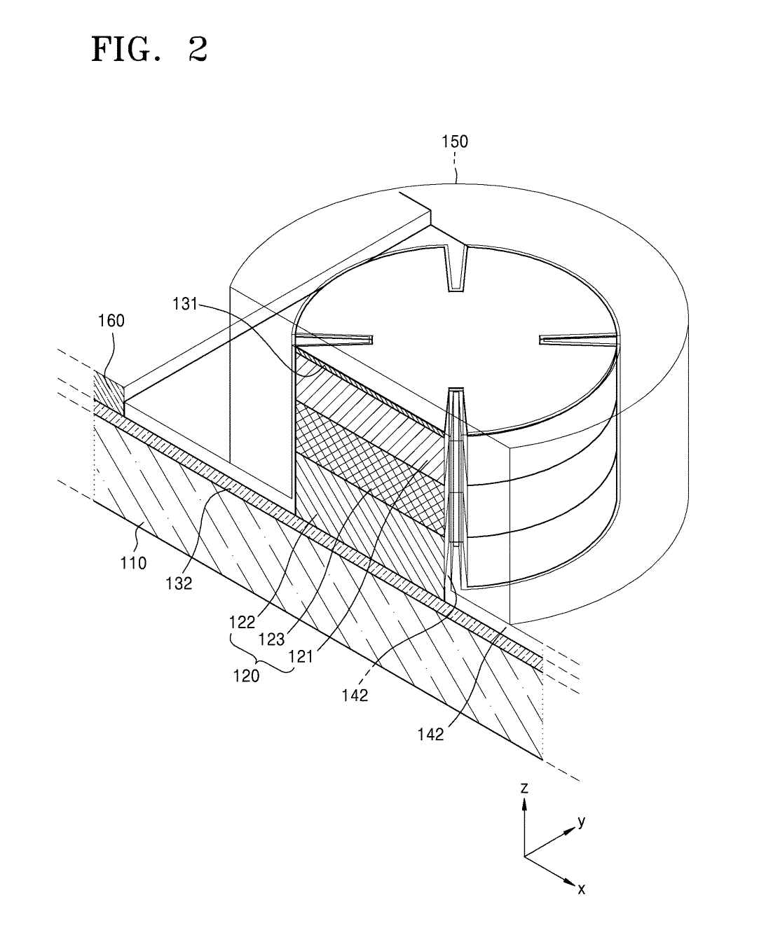

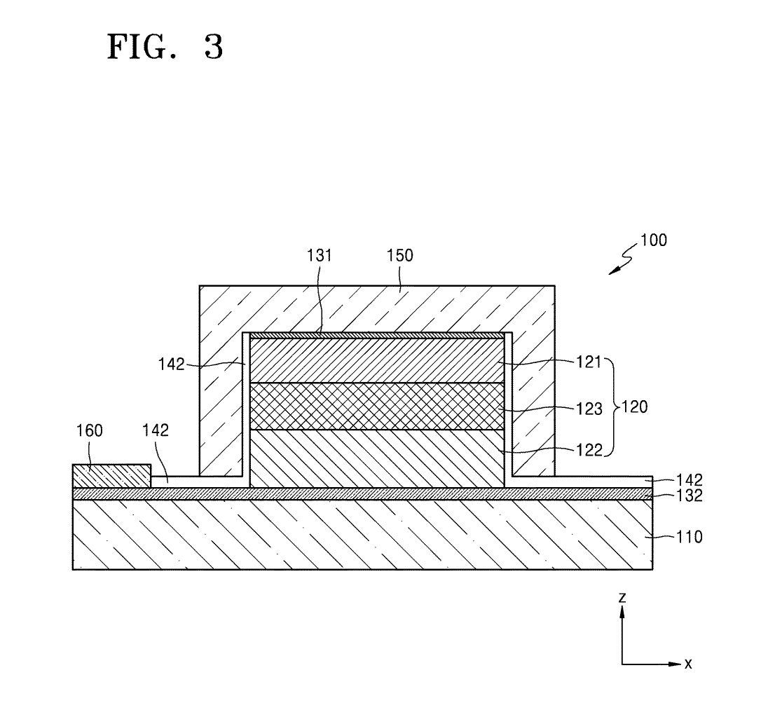

FIG. 1 is a perspective view of a semiconductor laser device 100 according to an exemplary embodiment. FIG. 2 is a partial cutaway perspective view of the semiconductor laser device 100 of FIG. 1, and FIG. 3 is a cross-sectional view of the semiconductor laser device 100 of FIG. 1.

Referring to FIGS. 1 through 3, the semiconductor laser device 100 includes a substrate 110 and a semiconductor laser resonator that is provided on the substrate 110 and generates a laser beam by absorbing external energy. The substrate 110 may be a semiconductor substrate, but is not limited thereto, and may be formed of any material, such as glass. In detail, the substrate 110 may be an indium phosphide (InP) substrate, but is not limited thereto. The semiconductor laser resonator may include a gain medium layer 120 that generates a laser beam by absorbing energy via optical pumping or electric pumping.

The gain medium layer 120 may include an active layer 123 that includes a semiconductor material. The active layer 123 may include, for example, a III-V group semiconductor material or a II-VI group semiconductor material. Alternatively, the active layer 123 may include quantum dots. In detail, the active layer 123 may include a multi-quantum wall including indium gallium arsenide (InGaAs), aluminum gallium arsenide (AlGaAs), indium gallium arsenide phosphide (InGaAsP), or aluminum gallium indium phosphide (AlGaInP), but is not limited thereto. The gain medium layer 120 may further include first and second clad layers 121 and 122 respectively provided on upper and lower portions of the active layer 123.

The first clad layer 121 is provided on a first surface of the active layer 123 (a top surface of the active layer 123 in FIG. 3), and may include an n- or p-type semiconductor material. In detail, the first clad layer 121 may include an n-type InP or a p-type InP, but is not limited thereto. The second clad layer 122 may be provided on a second surface of the active layer 123 (a bottom surface of the active layer 123 in FIG. 3). If the first clad layer 121 includes an n-type semiconductor material, the second clad layer 122 may include a p-type semiconductor material. Alternatively, if the first clad layer 121 includes a p-type semiconductor material, the second clad layer 122 may include an n-type semiconductor material. In detail, the second clad layer 122 may include a p-type InP or an n-type InP, but is not limited thereto.

A first contact layer 131 may be provided on a top surface of the first clad layer 121. The first contact layer 131 may have a shape corresponding to the gain medium layer 120. However, the shape of the first contact layer 131 is not limited thereto, and may vary. A shape of the gain medium layer 120 will be described in detail later. If the first clad layer 121 includes an n-type semiconductor material, the first contact layer 131 may include an n-type semiconductor material, and if the first clad layer 121 includes a p-type semiconductor material, the first contact layer 131 may include a p-type semiconductor material. In detail, the first contact layer 131 may include an n-type InGaAs or a p-type InGaAs, but is not limited thereto. An electrode (not shown) electrically connected to the first contact layer 131 may be further provided.

A second contact layer 132 may be provided on a bottom surface of the second clad layer 122. The second contact layer 132 may be provided on a top surface of the substrate 110. If the second clad layer 122 includes a p-type semiconductor material, the second contact layer 132 may include a p-type semiconductor material, and if the second clad layer 122 includes an n-type semiconductor material, the second contact layer 132 may include an n-type semiconductor material. In detail, the second contact layer 132 may include a p-type InGaAs or an n-type InGaAs, but is not limited thereto. An electrode 160 that is electrically connected to the second contact layer 132 may be further provided on the substrate 110. If the second contact layer 132 includes a p-type semiconductor material, the electrode 160 may be a p-type electrode, and if the second contact layer 132 includes an n-type semiconductor material, the electrode 160 may be an n-type electrode.

A metal layer 150 may be further provided to cover the gain medium layer 120 and the first contact layer 131. The metal layer 150 is provided outside the gain medium layer 120 to confine, in the gain medium layer 120, a laser beam generated by the gain medium layer 120. The metal layer 150 may include silver (Ag), gold (Au), copper (Cu), or aluminum (Al), but is not limited thereto and may include any metal material.

A buffer layer 142 may be further provided between the metal layer 150 and the gain medium layer 120. The buffer layer 142 may be provided between the metal layer 150 and a side surface of the gain medium layer 120. The buffer layer 142 may buffer an optical loss that may occur when the laser beam generated by the gain medium layer 120 contacts the metal layer 150. The buffer layer 142 may include a material having a refractive index different from the gain medium layer 120. In detail, the buffer layer 142 may include a material having a refractive index smaller than the gain medium layer 120. For example, the buffer layer 142 may include silicon oxide or silicon nitride, but is not limited thereto. The buffer layer 142 may extend from the side surface of the gain medium layer 120 to cover the second contact layer 132.

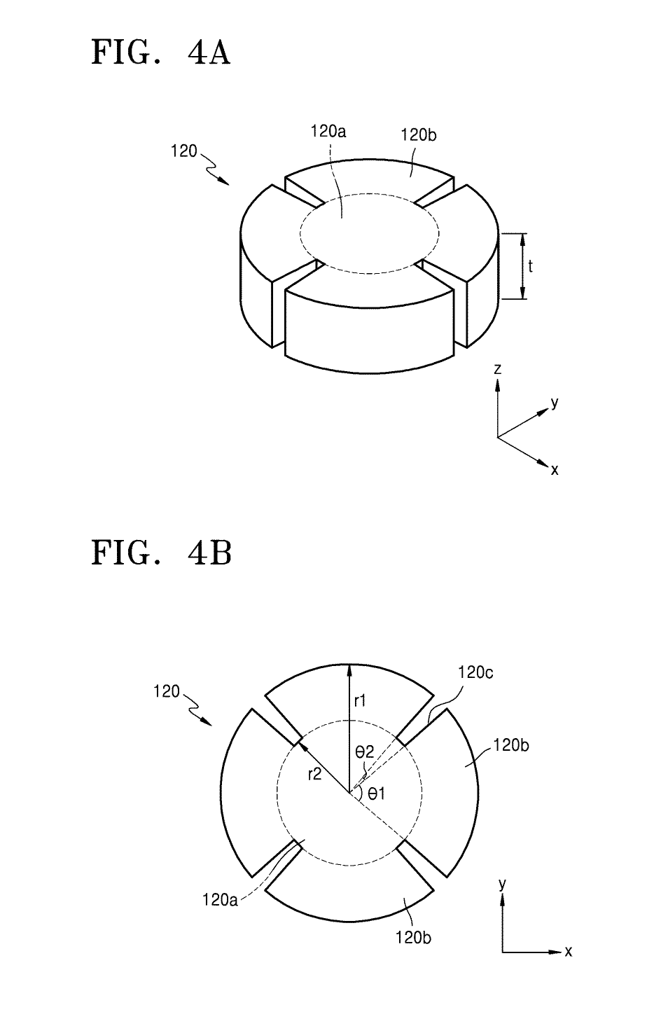

FIGS. 4A and 4B are respectively a perspective view and a plan view of the gain medium layer, according to an exemplary embodiment.

Referring to FIGS. 4A and 4B, the gain medium layer 120 includes a central portion 120a and a plurality of protrusions 120b in an outer region of the central portion 120a. The protrusions 120b may be arranged periodically around the outer region of the central portion 120a, and a plurality of recessed portions 120c may be formed between the protrusions 120b at regular intervals from each other. In FIGS. 4A and 4B, the four protrusions 120b having the same shape are provided in the outer region of the central portion 120a.

The central portion 120a of the gain medium layer 120 may have, for example, a circular plane shape. In FIG. 4A, t denotes a thickness of the gain medium layer 120. The gain medium layer 120 may have a thickness t in a micro-size or a nano-size, but is not limited thereto. For example, the gain medium layer 120 may have a thickness lower than or equal to about 500 nm.

In FIG. 4B, r1 denotes an outer radius of the gain medium layer 120, and r2 denotes an inner radius of the gain medium layer 120. The gain medium layer 120 may have an outer diameter in a micro-size or a nano-size. The outer diameter of the gain medium layer 120 may be lower than or equal to about 10 μm, but is not limited thereto. For example, the outer radius r1 of the gain medium layer may be from about 100 nm to about 5,000 nm, and the inner radius r2 of the gain medium layer 120 may be from about 100 nm to about 4,000 nm. Here, a ratio of the inner radius r2 to the outer radius r1, e.g., r2/r1, may be from about 0.02 to about 1. Also, θ1 and θ2 respectively denote an angle of the protrusion 120b and an angle of the recessed portion 120c. Here, the angle θ1 of the protrusion 120b may be from about 5° to about 175°. Since the protrusion 120b and the recessed portion 120c exist as a pair, the angle θ2 of the recessed portion 120c may be from about 175° to about 5° considering at least two pairs of the protrusion 120b and the recessed portion 120c may be provided. The gain medium layer 120 having such a minute size may be formed via a patterning process, such as photolithography, e-beam lithography, plasmonic lithography, or a focused ion beam (FIB) technique.

As described hereinabove, the central portion 120a of the gain medium layer 120 has a circular plane shape, but as will be described below, the central portion 120a may have another plane shape. For example, the central portion 120a of the gain medium layer 120 may have a quadrangular plane shape, such as a rectangular or a square plane shape. Also, as described hereinabove, the four protrusions 120b having the same shape are provided in the outer region of the central portion 120a of the gain medium layer 120, but the number of the protrusions 120b may vary. For example, the number of the protrusions 120b may be from 2 to 10. Also, hereinabove, the protrusions 120b have the same shape, but may alternatively have different shapes.

In the gain medium layer 120 having such a structure, the protrusions 120b are arranged in the periodic structure along the outer region of the central portion 120a, and thus, a laser beam generated by the gain medium layer 120 may be confined as standing waves in at least one of the protrusions 120b. Confining the laser beam as standing waves in the protrusions 120b refers to a feature by which intensity of the laser beam may change according to time but the laser beam is confined at certain positions in the protrusions 120b. The intensity of the laser beam confined in the protrusions 120b may decrease towards a surface of the protrusions 120b. The laser beam generated by the gain medium layer 120 may be confined not only in the protrusions 120b but also in the central portion 120a.

As such, since the laser beam generated by the gain medium layer 120 is confined as standing waves in at least one of the protrusions 120b, a resonant mode of a desired wavelength may be easily selected as will be described later. Also, resonant modes that are not desired may be removed or a resonant mode that is desired may be effectively separated from other resonant modes. Accordingly, a Q-factor of the semiconductor laser resonator may be improved. A resonant mode may be selected and/or separated based on at least one of the number, shape, and size of the protrusions 120b and an interval between the protrusions 120b. Also, by providing the metal layer 150 outside the gain medium layer 120, the laser beam generated by the gain medium layer 120 may be efficiently confined.

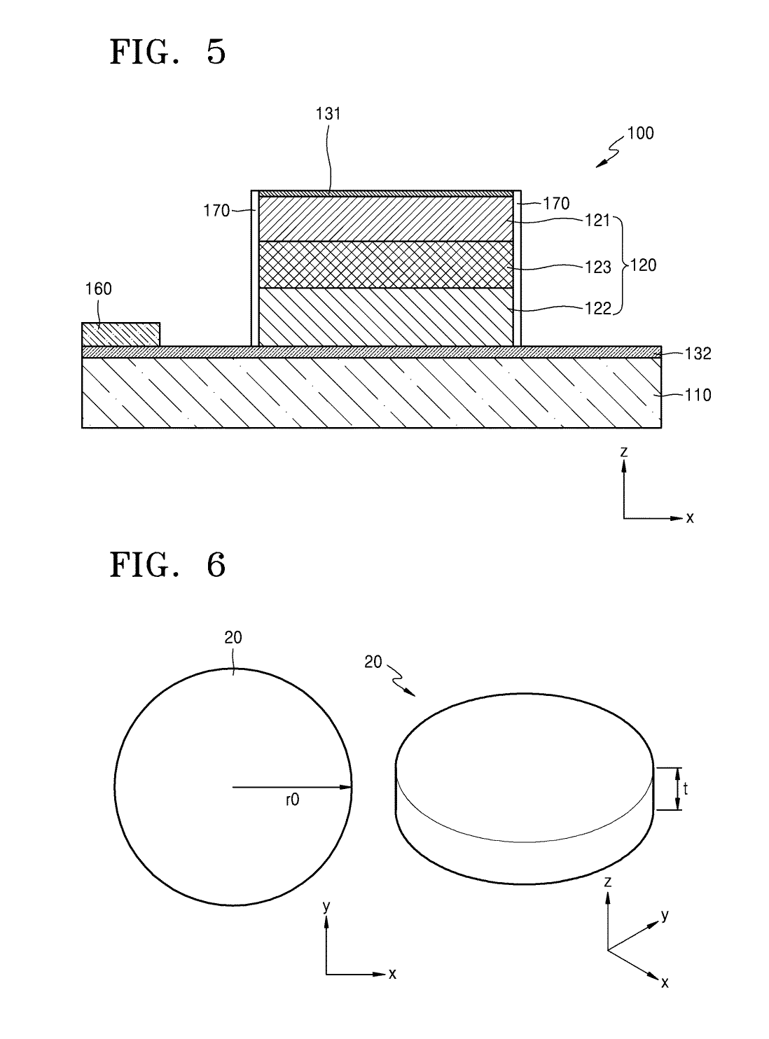

FIG. 5 is a cross-sectional view of the semiconductor laser device according to another exemplary embodiment.

Referring to FIG. 5, a dielectric layer 170 is provided to cover the gain medium layer 120. The dielectric layer 170 may be provided on a side surface of the gain medium layer 120. Such a dielectric layer 170 confines the laser beam generated by the gain medium layer 120. Accordingly, the dielectric layer 170 may include a material having a refractive index different from the gain medium layer 120. In detail, the dielectric layer 170 may include material having a refractive index smaller than the gain medium layer 120. The dielectric layer 170 may include, for example, silicon oxide or silicon nitride, but is not limited thereto.

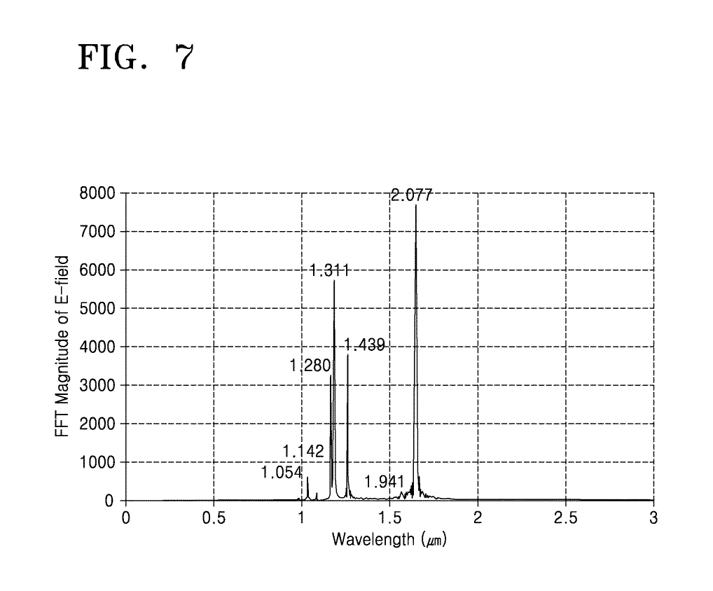

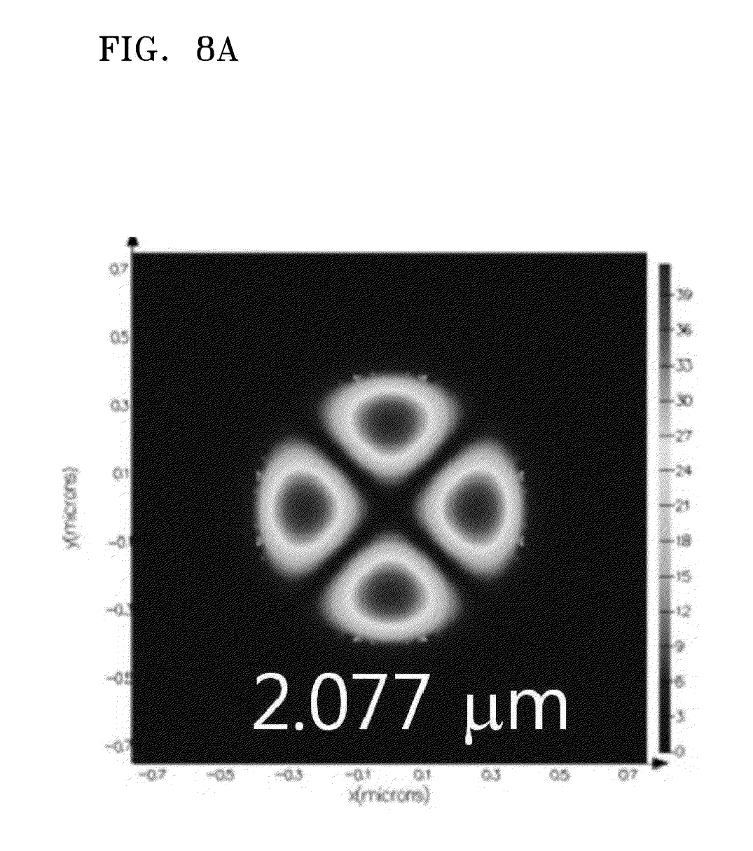

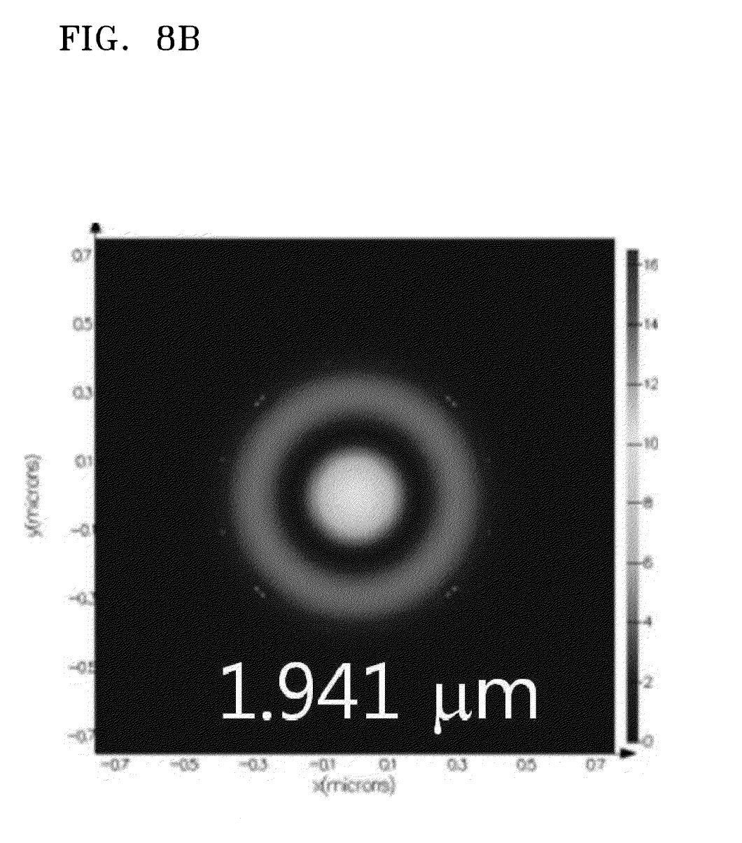

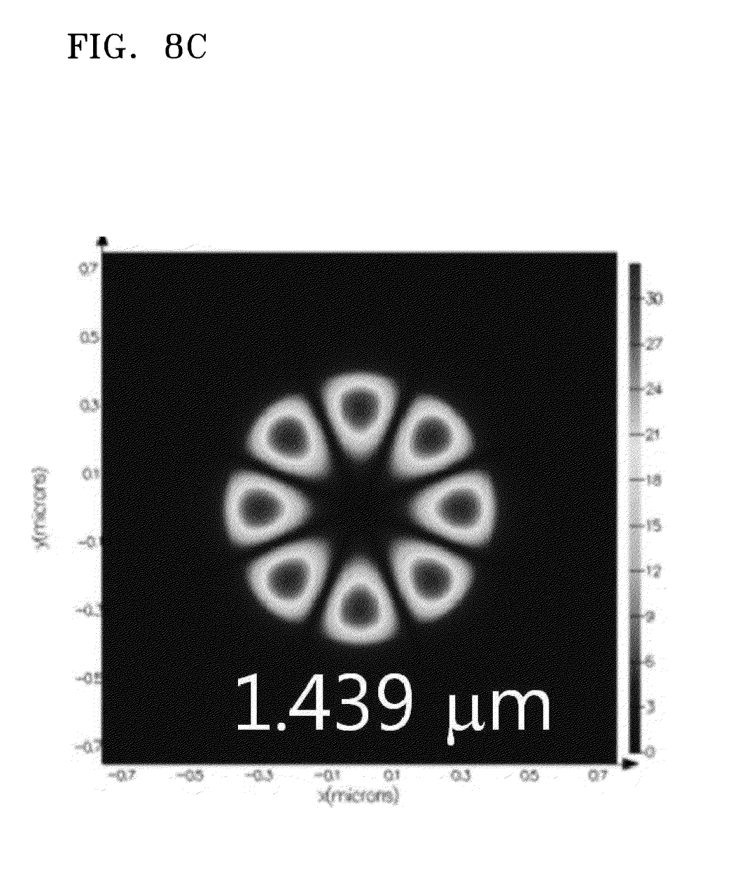

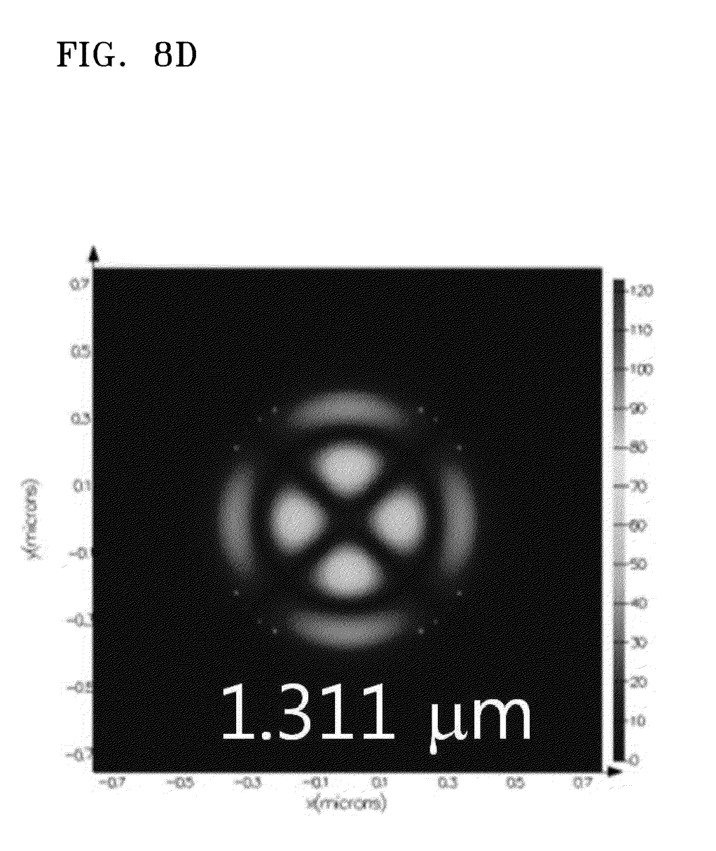

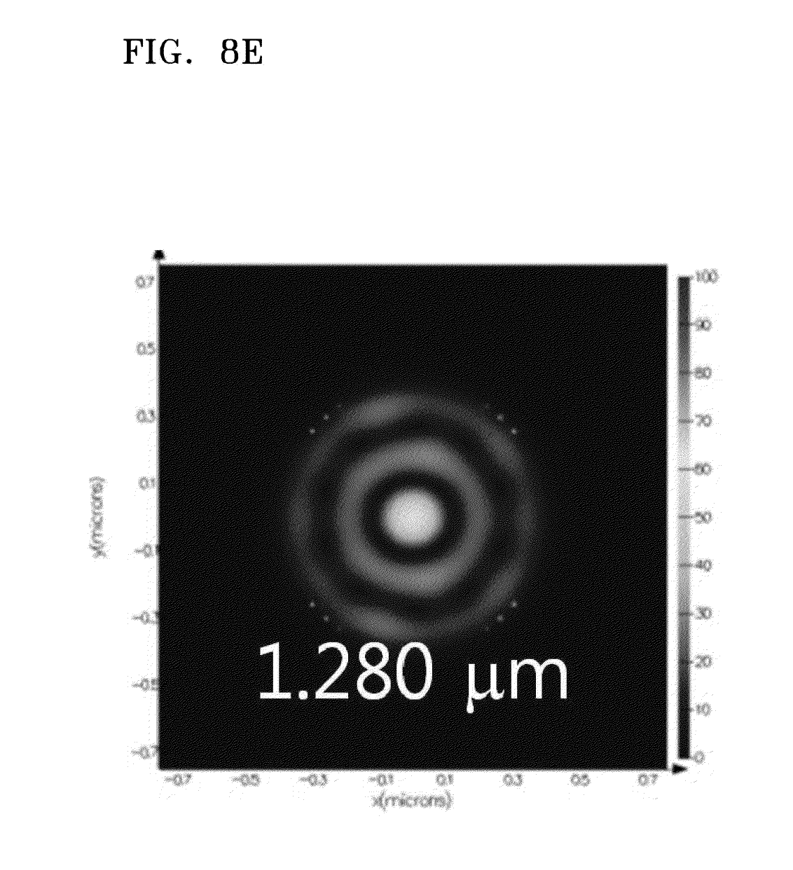

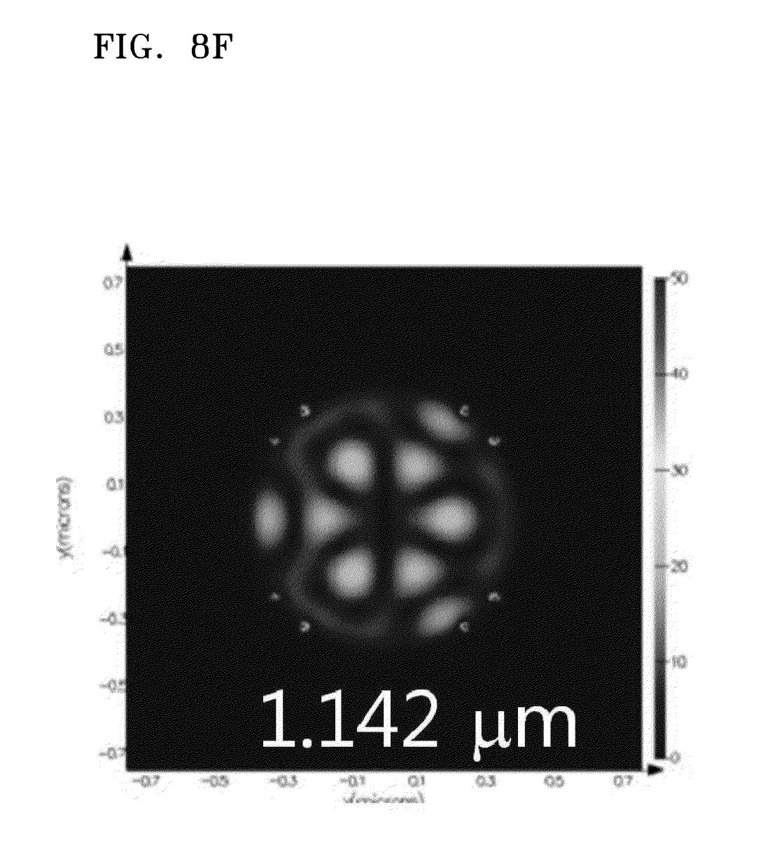

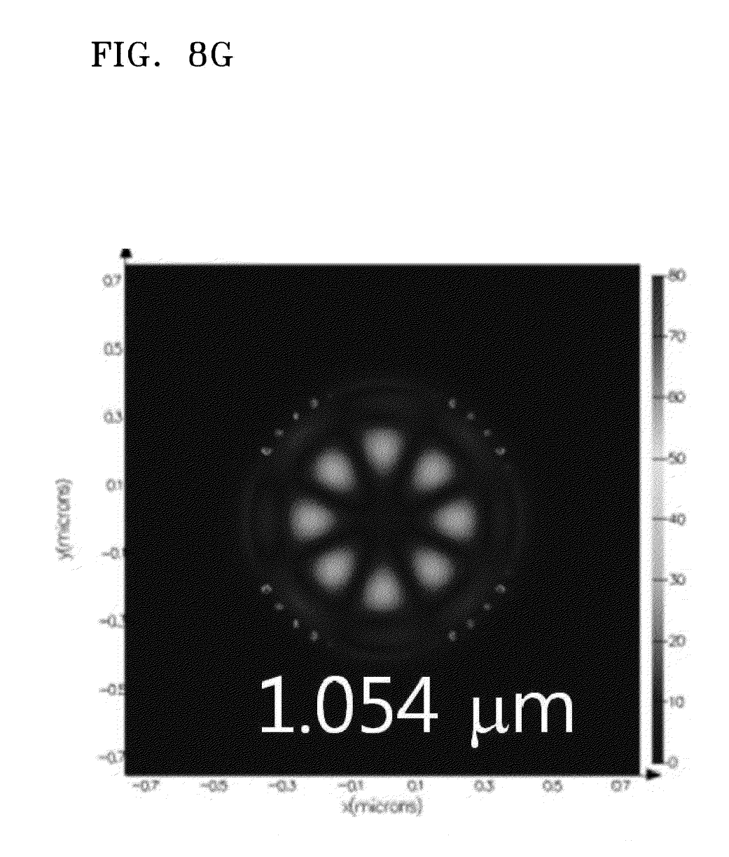

FIG. 6 is a plan view and a perspective view of a general cylindrical gain medium layer. FIG. 7 illustrates a spectrum of a laser beam generated by the general cylindrical gain medium layer of FIG. 6. In detail, FIG. 7 illustrates fast Fourier transform (FFT) magnitude of an electric field according to a wavelength of the laser beam. Also, FIGS. 8A through 8G illustrate intensity distributions of an electric field of the laser beam generated by the general cylindrical gain medium layer of FIG. 6. In detail, FIGS. 8A through 8G respectively illustrate intensity distributions of an electric field according to wavelengths of the laser beam. In FIGS. 8A through 8G, a red region indicates a region where intensity of an electric field is strong, and a blue region indicates a region where intensity of an electric field is weak. FIGS. 7 and 8A through 8G illustrate results obtained via simulation when the general cylindrical gain medium layer 20 of FIG. 6 is formed of InGaAs having a refractive index n of 3.55, has a radius r0 and a thickness t respectively of 400 nm and 200 nm, and is surrounded by Ag, and an electric dipole is set in a z-axis direction.

Referring to FIGS. 7 and 8A through 8G, a TM₂₁-like resonant mode of 2.077 μm wavelength, a TM₀₂-like resonant mode of 1.941 μm wavelength, a TM₄₁-like resonant mode of 1.439 μm wavelength, a TM₂₂-like resonant mode of 1.311 μm wavelength, a TM₀₃-like resonant mode of 1.280 μm wavelength, a hybrid resonant mode of 1.142 μm wavelength, and a hybrid resonant mode of 1.054 μm wavelength are generated in the general cylindrical gain medium layer 20 of FIG. 6. According to an exemplary embodiment, a TMₘₙ resonant mode denotes a transverse magnetic resonant mode representing an electromagnetic field in a resonator when a magnetic field is generated perpendicular to a proceeding direction of electromagnetic waves. In a resonator including the gain medium layer 20 of FIG. 6, a proceeding direction of an electromagnetic field is assumed to be a z-axis for convenience. Thus, in a TM resonant mode, a magnetic field is generated on an x-y plane that is perpendicular to the z-axis, and an electric field is generated on the z-axis. m and n are each an integer and respectively indicate a mode number of an azimuthal direction and a mode number of a radial direction. For example, TM₂₁ resonant mode is a TM resonant mode wherein a mode number of an azimuthal direction is 2 and a mode number of a radial direction is 1, and TM₂₂ resonant mode is a TM resonant mode wherein a mode number of an azimuthal direction is 2 and a mode number of a radial direction is 2. As such, since many resonant modes are generated in the general cylindrical gain medium layer 20 of FIG. 6, it is difficult to easily select a resonant mode of a desired wavelength from among the many resonant modes.

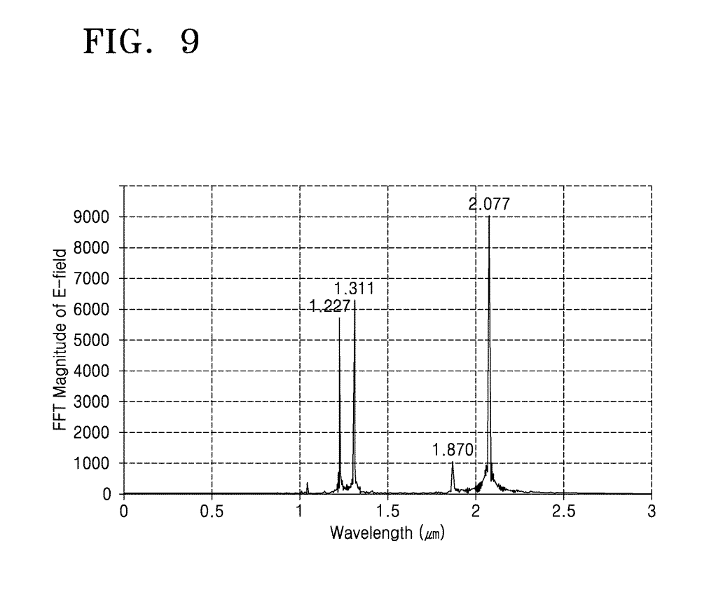

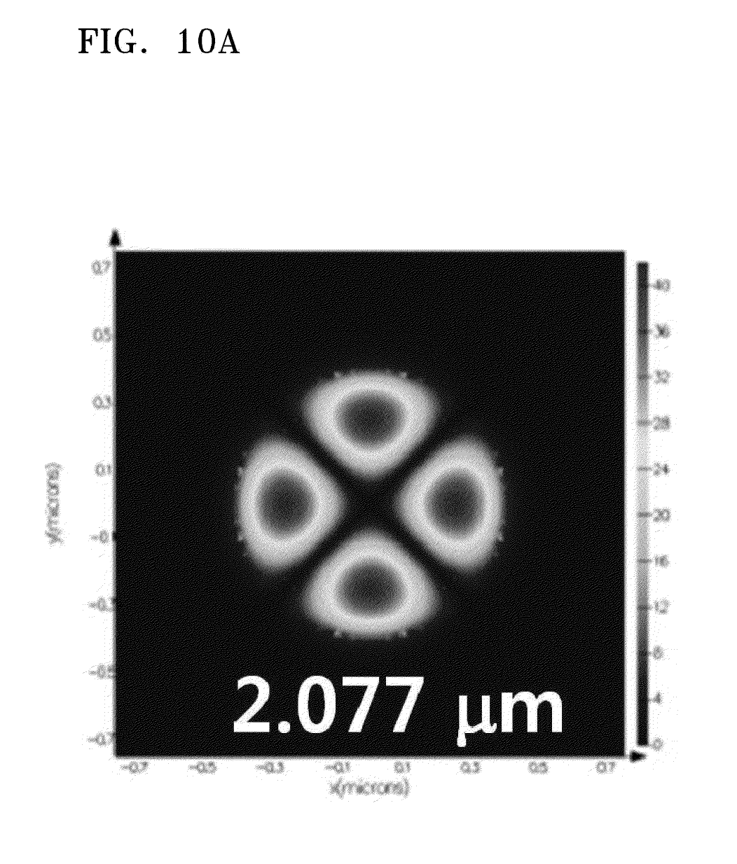

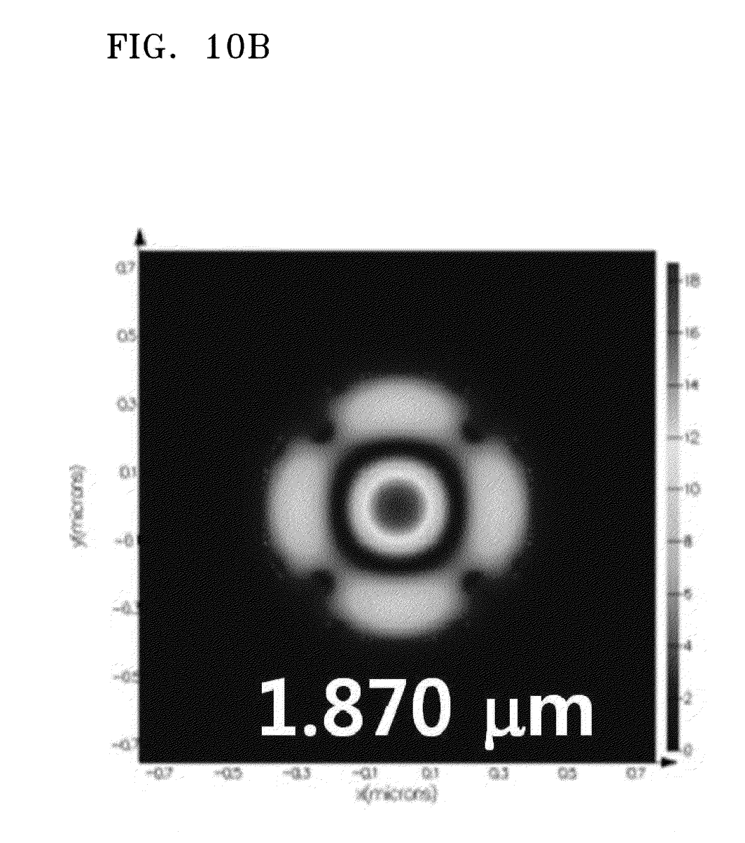

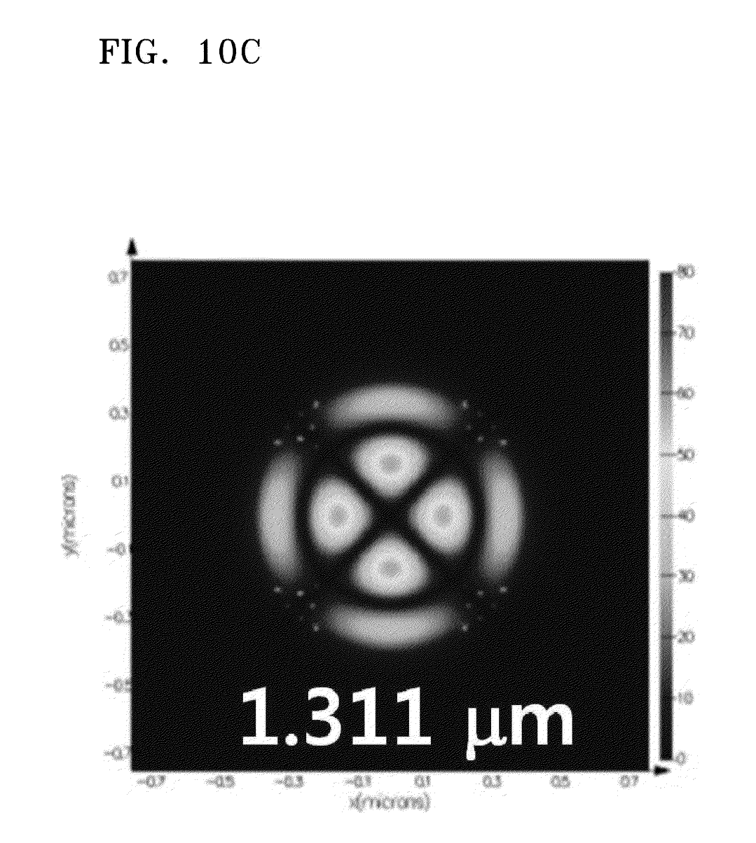

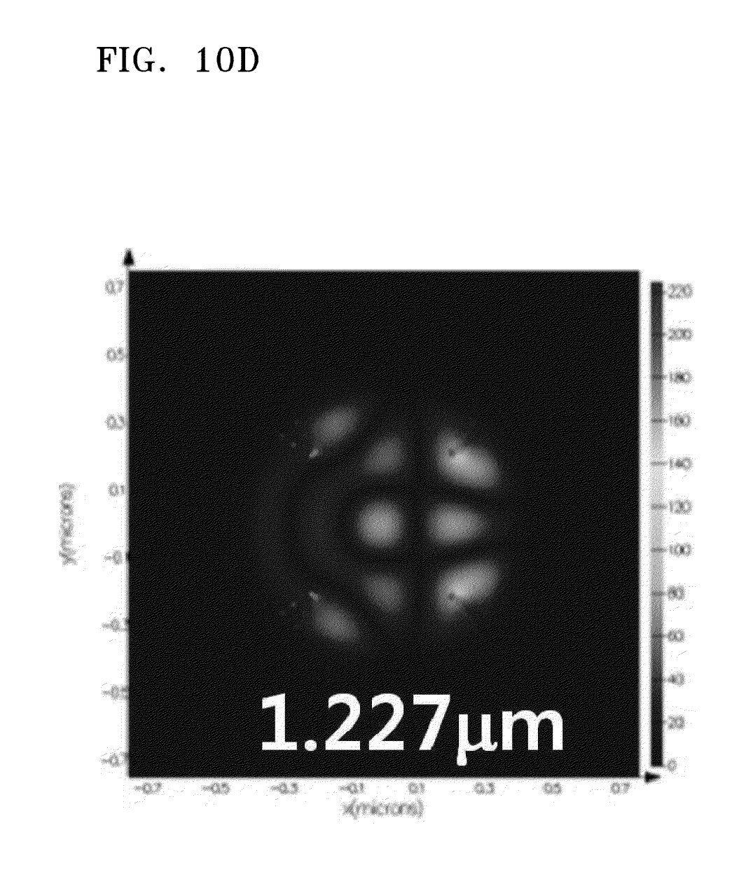

FIG. 9 illustrates a spectrum of the laser beam generated by the gain medium layer of 120 FIGS. 4A and 4B. In detail, FIG. 9 illustrates an FFT magnitude of an electric field according to wavelengths of the laser beam. Also, FIGS. 10A through 10D illustrate intensity distributions of an electric field of the laser beam generated by the gain medium layer 120 of FIGS. 4A and 4B. In detail, FIGS. 10A through 10D respectively illustrate intensity distributions of an electric field according to wavelengths of the laser beam. In FIGS. 10A through 10D, a red region indicates a region where intensity of an electric field is strong, and a blue region indicates a region where intensity of an electric field is weak. FIGS. 9 and 10A through 10D illustrate results obtained via simulation when the gain medium layer 120 of FIGS. 4A and 4B having the four protrusions 120b is formed of InGaAs having a refractive index n of 3.55, has an outer radius r1, an inner radius r2, a thickness t, an angle θ1 of the protrusion 120b, and an angle θ2 of the recessed portion 120c respectively of 400 nm, 300 nm (r2/r1=0.75), 200 nm, 84°, and 6°, and is surrounded by Ag, and an electric dipole is set in a z-axis direction.

Referring to FIGS. 9 and 10A through 10D, a TM₂₁-like resonant mode of 2.077 μm wavelength, a hybrid resonant mode of 1.870 μm wavelength, a TM₂₂-like resonant mode of 1.311 μm wavelength, and a hybrid resonant mode of 1.227 μm wavelength are generated in the gain medium layer 120 of FIGS. 4A and 4B. The laser beam generated by the gain medium layer 120 may be confined as standing waves in the protrusions 120b. Also, the laser beam may not only be confined in the protrusions 120b but also be confined in the central portion 120a according to a resonant mode. Also, as shown in FIGS. 10A through 10D, the intensity of the laser beam confined in the protrusions 120b decreases towards the surface of the protrusions 120b.

As described above, FIG. 7 illustrates a spectrum of the laser beam generated by the general cylindrical gain medium layer 20 of FIG. 6 and FIG. 9 illustrates a spectrum of the laser beam generated by the gain medium layer 120 of FIGS. 4A and 4B.

Referring to FIGS. 7 and 9, the resonant mode of 1.439 μm wavelength, the resonant mode of 1.142 μm wavelength, and the resonant mode of 1.054 μm wavelength from among the resonant modes generated in the general cylindrical medium layer 20 of FIG. 6 are not generated in the gain medium layer 120 of FIGS. 4A and 4B. Accordingly, only a desired resonant mode may be easily selected by removing undesired resonant modes in the gain medium layer 120 of FIGS. 4A and 4B. Also, the resonant mode of 2.077 μm wavelength generated in the gain medium layer 120 of FIGS. 4A and 4B has a larger FFT magnitude of an electric field compared to the resonant mode of 2.077 μm wavelength generated in the general cylindrical gain medium layer 20 of FIG. 6. Accordingly, a resonant mode of a desired wavelength may be further strengthened in the gain medium layer 120 of FIGS. 4A and 4B.

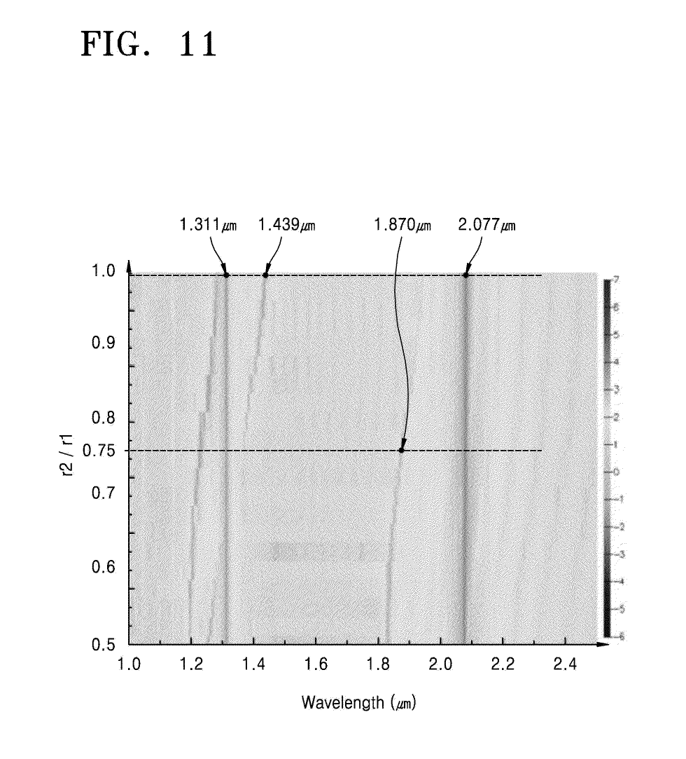

FIG. 11 is a diagram for describing a relationship between wavelengths and a ratio of the inner radius r2 to the outer radius r1 of the gain medium layer 120 of FIGS. 4A and 4B. FIG. 11 illustrates results obtained via simulation when the gain medium layer 120 is formed of InGaAs having the refractive index n of 3.55, has the outer radius r1, the thickness t, the angle θ1 of the protrusion 120b, and the angle θ2 of the recessed portion 120c respectively of 400 nm, 200 nm, 84°, and 6°, and is surrounded by Ag.

In FIG. 11, the outer radius r1 of the gain medium layer 120 has the same uniform value as the radius r0 of the gain medium layer 20 of FIG. 6, whereas a value of the inner radius r2 of the gain medium layer 120 is gradually decreased. Referring to FIG. 11, when the ratio of the inner radius r2 to the outer radius r1 is 1, the gain medium layer 120 is the same as the general cylindrical gain medium layer 20 of FIG. 6, and the spectrum of the laser beam and the intensity distributions of the electric field are shown in FIGS. 7 and 8A through 8G. Also, the spectrum of the laser beam and the intensity distributions of the electric field when r2/r1 is 0.75 are shown in FIGS. 9 and 10A through 10D.

When r2/r1 is equal to or higher than 0.75, the resonant mode of 1.439 μm wavelength generated in the general cylindrical gain medium layer 20 of FIG. 7 is gradually weakened as the inner radius r2 of the gain medium layer 120 is decreased, whereas the resonant mode of 1.870 μm wavelength generated in the gain medium layer 120 of FIG. 9 is gradually strengthened as the inner radius r2 of the gain medium layer 120 is decreased. Alternatively, when r2/r1 is lower than or equal to 0.75, the resonant mode of 1.439 μm wavelength generated in the general cylindrical gain medium layer 20 of FIG. 7 disappears and then appears as the inner radius r2 of the gain medium layer 120 is decreased, whereas the resonant mode of 1.870 urn wavelength generated in the gain medium layer 120 of FIG. 9 is gradually strengthened as the inner radius r2 of the gain medium layer 120 is decreased. Meanwhile, the resonant mode of 2.077 μm wavelength exists regardless of a value of r2/r1 because the resonant mode of 2.077 μm wavelength is formed symmetric in 90° such as not to be affected by the inner radius r2 of FIGS. 4A and 4B.

As such, by adjusting the ratio of the inner radius r2 to the outer radius r1 of the gain medium layer 120, a resonant mode of an undesired wavelength may be removed or a resonant mode of a desired wavelength may be generated.

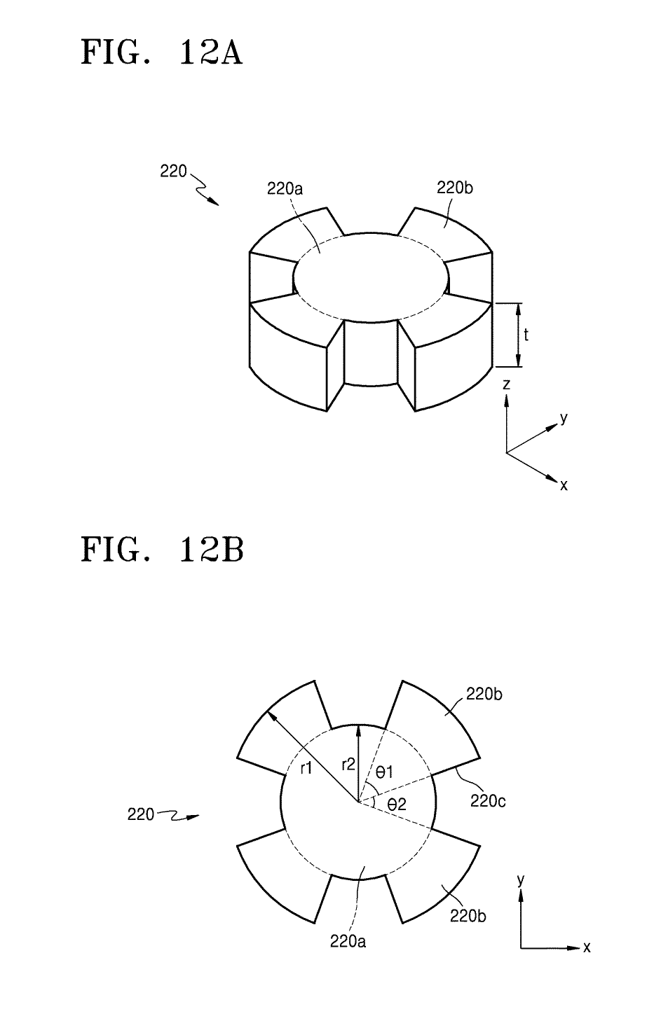

FIGS. 12A and 12B are respectively a perspective view and a plan view of a gain medium layer according to another exemplary embodiment.

Referring to FIGS. 12A and 12B, the gain medium layer 220 includes a central portion 220a and a plurality of protrusions 220b which are protrudably provided in an outer region of the central portion 220a. The protrusions 220b may be arranged in a periodic structure along the outer region of the central portion 220a, and a plurality of recessed portions 220c may be formed between the plurality of protrusions 220b at regular intervals. In FIGS. 12A and 12B, the four protrusions 220b having the same shape are provided in the outer region of the central portion 220a. The central portion 220a of the gain medium layer 220 may have a circular plane shape. In FIG. 12A, t denotes a thickness of the gain medium layer 220, and in FIG. 12B, r1 denotes an outer radius of the gain medium layer 220 and r2 denotes a radius of the central portion 220a, e.g., an inner radius of the gain medium layer 220. Also, θ1 and θ2 respectively denote angles of the protrusion 220b and the recessed portion 220c. The gain medium layer 220 of FIGS. 12A and 12B may have the outer radius r1 and the angle θ2 of the recessed portion 220c larger than the gain medium layer 120 of FIGS. 4A and 4B.

According to the gain medium layer 220, since the protrusions 220b are arranged in the periodic structure along the outer region of the central portion 220a, a laser beam generated by the gain medium layer 220 may be confined as standing waves in at least one of the protrusions 220b. An intensity of the laser beam confined in the protrusions 220b may decrease towards a surface of the protrusions 220b. Meanwhile, the laser beam generated by the gain medium layer 220 may be confined not only in the protrusions 220b but also in the central portion 220a.

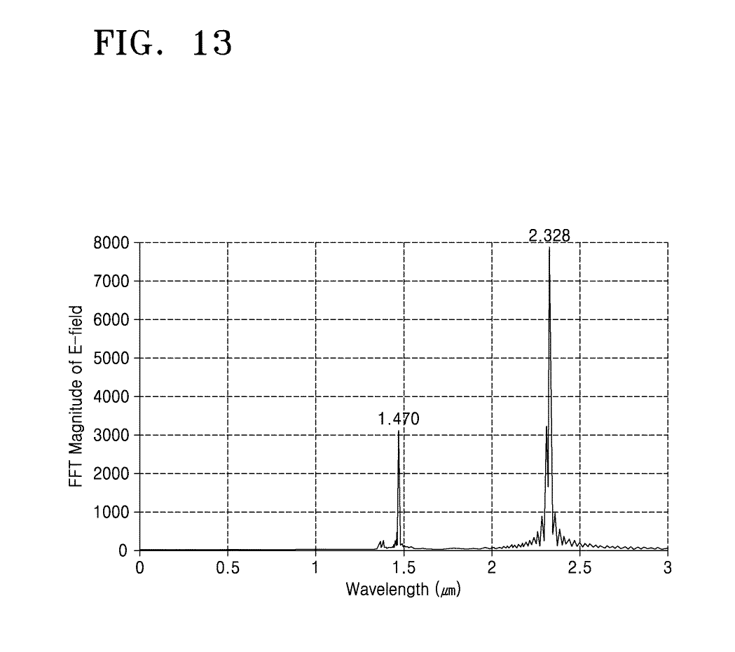

FIG. 13 illustrates a spectrum of the laser beam generated by the gain medium layer 220 of FIGS. 12A and 12B. In detail, FIG. 13 illustrates an FFT magnitude of an electric field according to wavelengths of the laser beam. Also, FIGS. 14A and 14B illustrate intensity distributions of an electric field of the laser beam generated by the gain medium layer 220 of FIGS. 12A and 12B. In detail, FIGS. 14A and 14B respectively illustrate intensity distributions of an electric field according to wavelengths of the laser beam. In FIGS. 14A and 14B, a red region indicates a region where intensity of an electric field is high and a blue region indicates a region where intensity of an electric field is low. FIGS. 13, 14A and 14B illustrate results obtained via simulation when the gain medium layer 220 of FIGS. 12A and 12B having the four protrusions 220b is formed of InGaAs having a refractive index n of 3.55, has an outer radius r1, an inner radius r2, a thickness t, an angle θ1 of the protrusion 220b, and an angle θ2 of the recessed portion 220c respectively of 450 nm, 400 nm (r2/r1=0.89), 200 nm, 60°, and 30°, and is surrounded by Ag, and an electric dipole is set in a z-axis direction.

Referring to FIGS. 13, 14A, and 14B, a TM₂₁-like resonant mode of 2.328 μm wavelength and a TM₂₂-like resonant mode of 1.470 μm wavelength are generated in the gain medium layer 220 of FIGS. 12A and 12B. Here, the laser beam generated by the gain medium layer 220 may be confined as standing waves in the protrusions 220b. The intensity of the laser beam confined in the protrusions 220b may decrease towards the surface of the protrusions 220b.

As described above, FIG. 7 illustrates the spectrum of the laser beam generated by the general cylindrical gain medium layer 20 of FIG. 6 and FIG. 13 illustrates the spectrum of the laser beam generated by the gain medium layer 220 of FIGS. 12A and 12B.

Referring to FIGS. 7 and 13, the resonant mode of 1.439 μm wavelength, the resonant mode of 1.280 μm wavelength, the resonant mode of 1.142 μm wavelength, and the resonant mode of 1.054 μm wavelength from among the resonant modes generated in the general cylindrical medium layer 20 of FIG. 6 are not generated in the gain medium layer 220 of FIGS. 12A and 12B. Accordingly, only a desired resonant mode may be easily selected by removing undesired resonant modes in the gain medium layer 220 of FIGS. 12A and 12B. Also, the TM₂₁-like resonant mode of 2.077 μm wavelength and the TM₂₂-like resonant mode of 1.311 μm wavelength generated in the general cylindrical gain medium layer 20 of FIG. 6 are respectively changed to the TM₂₁-like resonant mode of 2.328 μm wavelength and the TM₂₂-like resonant mode of 1.470 μm wavelength in the gain medium layer 220 of FIGS. 12A and 12B. As such, a wavelength of a certain resonant mode increases in the gain medium layer 220 of FIGS. 12A and 12B compared to the general cylindrical gain medium layer 20 of FIG. 6, because a size of the gain medium layer 220 of FIGS. 12A and 12B is larger than that of the general cylindrical gain medium layer 20 of FIG. 6. Also, as shown in FIGS. 7 and 13, an interval between the TM₂₁-like resonant mode of 2.328 μm wavelength and the TM₂₂-like resonant mode of 1.470 μm wavelength generated in the gain medium layer 220 of FIGS. 12A and 12B is greater than an interval between the TM₂₁-like resonant mode of 2.077 μm wavelength and the TM₂₂-like resonant mode of 1.311 μm wavelength generated in the general cylindrical gain medium layer 20 of FIG. 6. Accordingly, resonant modes may be easily separated or selected in the gain medium layer 220 of FIGS. 12A and 12B compared to the general cylindrical gain medium layer 20 of FIG. 6.

FIG. 15 is a diagram for describing a relationship between wavelengths and a ratio of the outer radius r1 to the inner radius r2 of the gain medium layer 220 of FIGS. 12A and 12B. FIG. 15 illustrates results obtained via simulation when the gain medium layer 220 is formed of InGaAs having the refractive index n of 3.55, has the inner radius r2, the thickness t, the angle θ1 of the protrusion 220b, and the angle θ2 of the recessed portion 220c respectively of 400 nm, 200 nm, 60°, and 30°, and is surrounded by Ag.

In FIG. 15, the inner radius r2 of the gain medium layer 220 has the same uniform value as the radius r0 of the cylindrical gain medium layer 20 of FIG. 6, whereas the radius r1 of the gain medium layer 220 is gradually increased. Referring to FIG. 15, when r1/r2 is 1, the gain medium layer 220 is the same as the general cylindrical gain medium layer 20 of FIG. 6, and the spectrum of the laser beam and the intensity distributions of the electric field are shown in FIGS. 7 and 8A through 8G. Also, the spectrum of the laser beam and the intensity distributions of the electric field when r1/r2 is 1.125 are shown in FIGS. 13, 14A, and 14B.

When r1/r2 is lower than or equal to 1.125, the resonant mode of 1.459 μm generated in the cylindrical gain medium layer 20 of FIG. 7 is gradually weakened as the outer radius r1 is increased. Also, when r1/r2 becomes 1.125 as the outer radius r1 increases, the TM₂₁-like resonant mode of 2.077 μm wavelength and the TM₂₂-like resonant mode of 1.311 μm wavelength generated in the general cylindrical gain medium layer 20 of FIG. 6 move to the TM₂₁-like resonant mode of 2.328 μm wavelength and the TM₂₂-like resonant mode of 1.470 μm wavelength. Also, when r1/r2 is higher than or equal to 1.125, the resonant mode of 1.439 μm wavelength generated in the general cylindrical gain medium layer 20 of FIG. 6 disappears as the outer radius r1 increases. As such, by adjusting the ratio of the outer radius r1 to the inner radius r2 of the gain medium layer 220, a resonant mode of an undesired wavelength may be removed or a resonant mode of a desired wavelength may be generated.

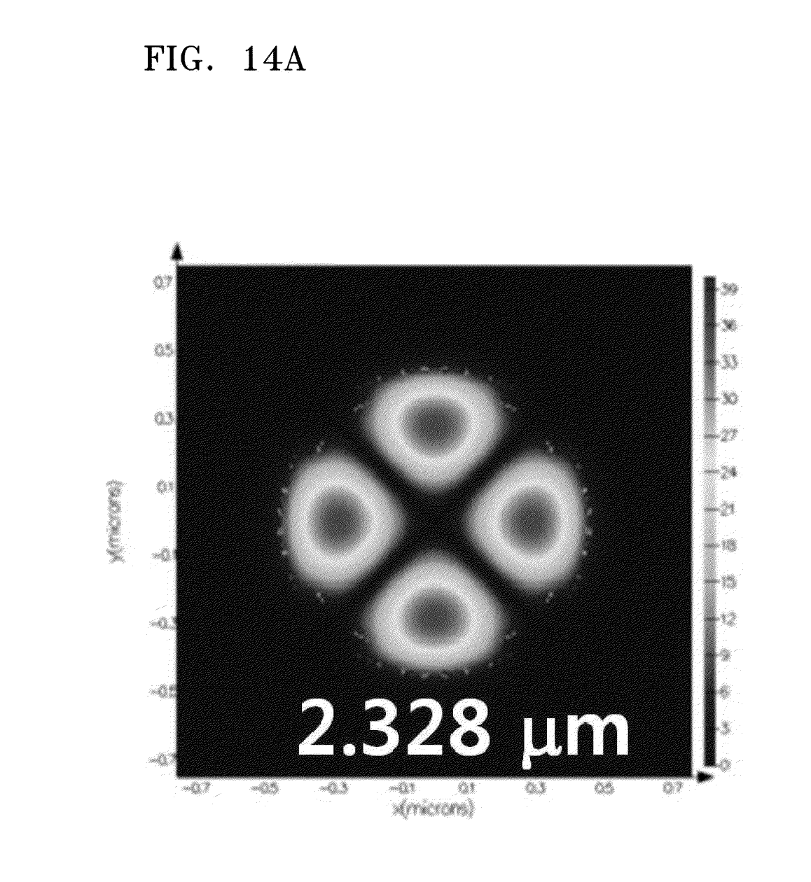

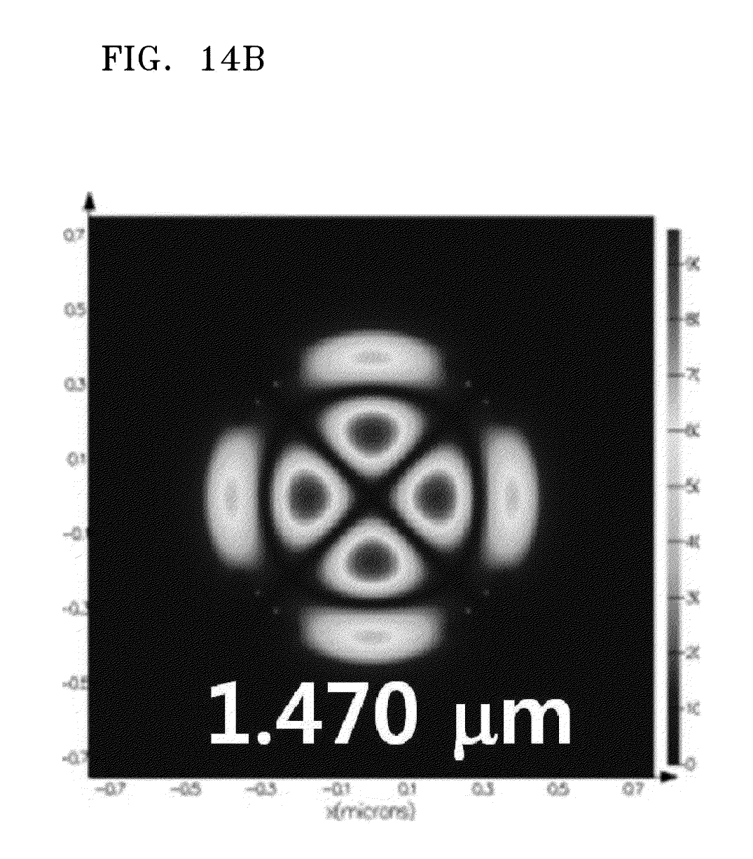

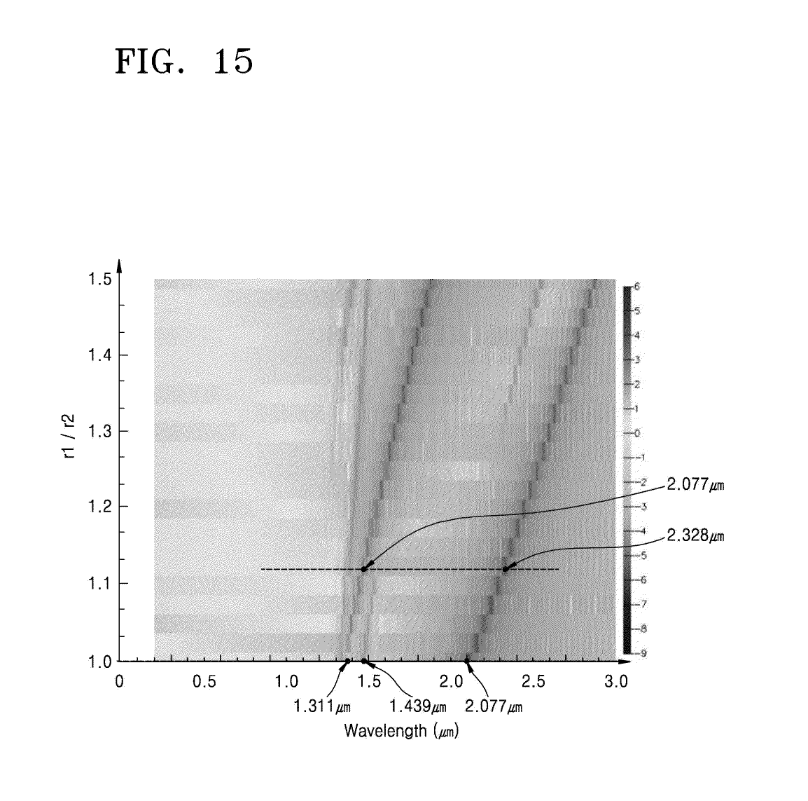

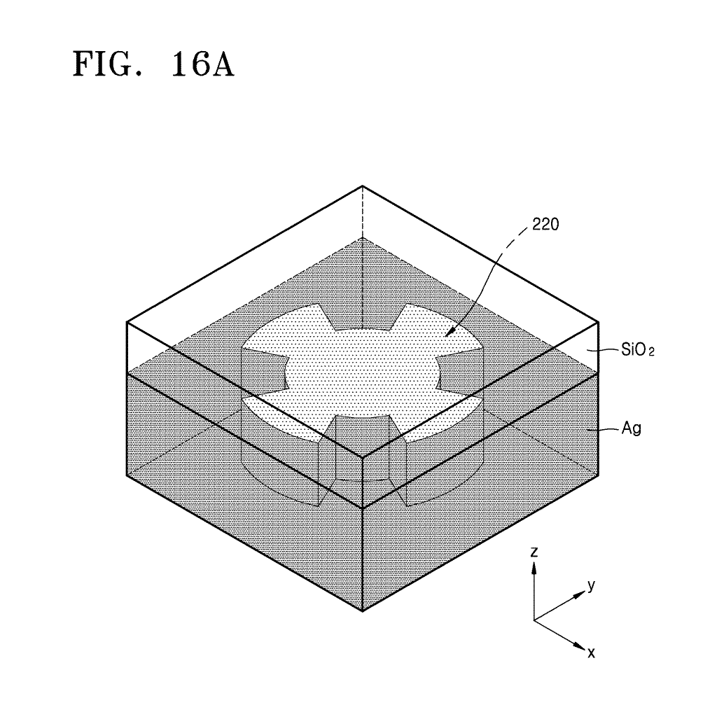

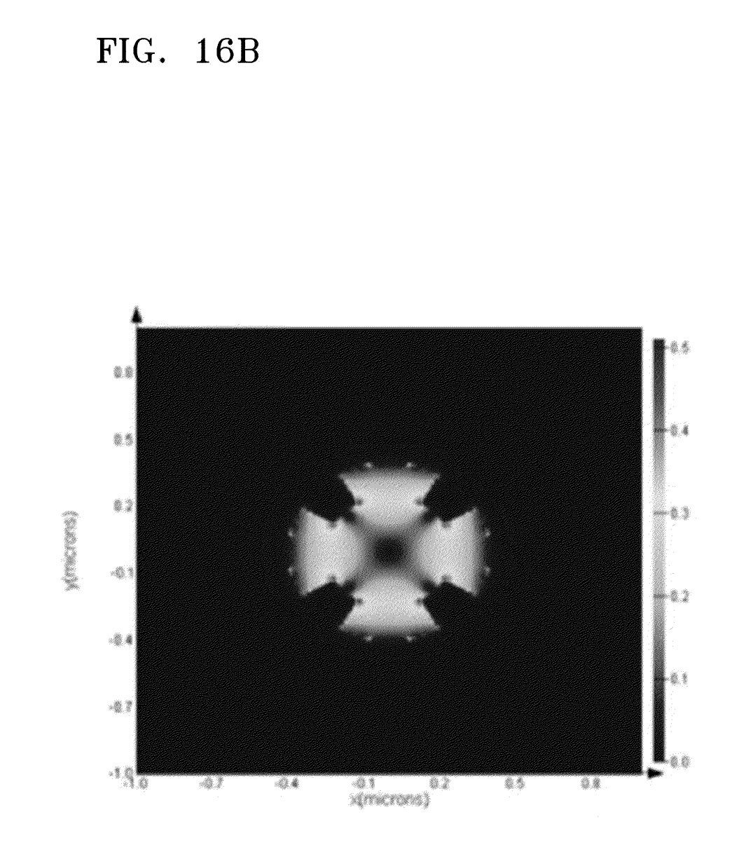

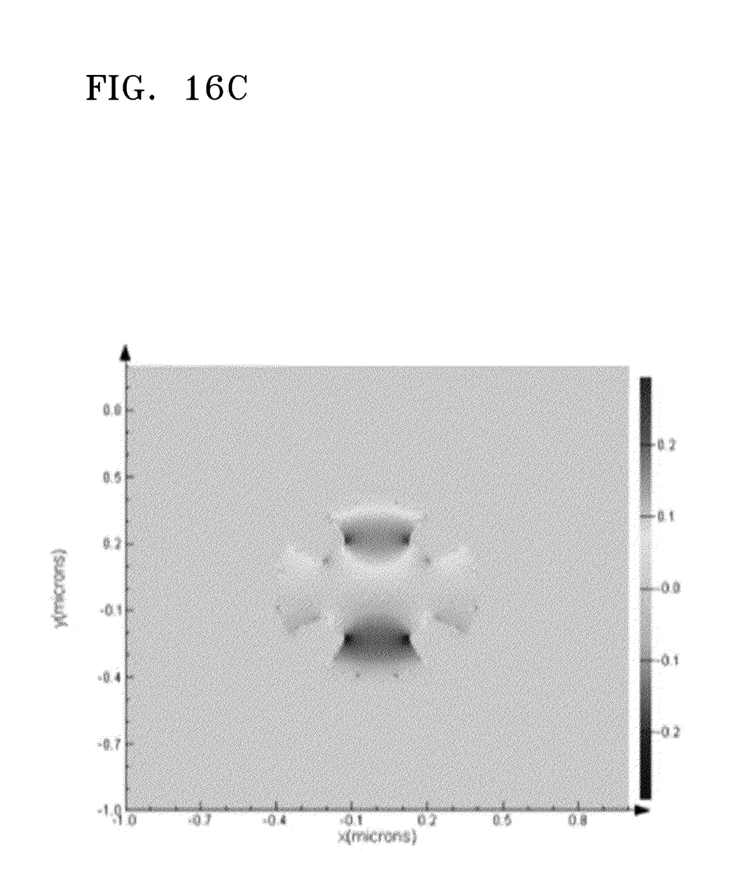

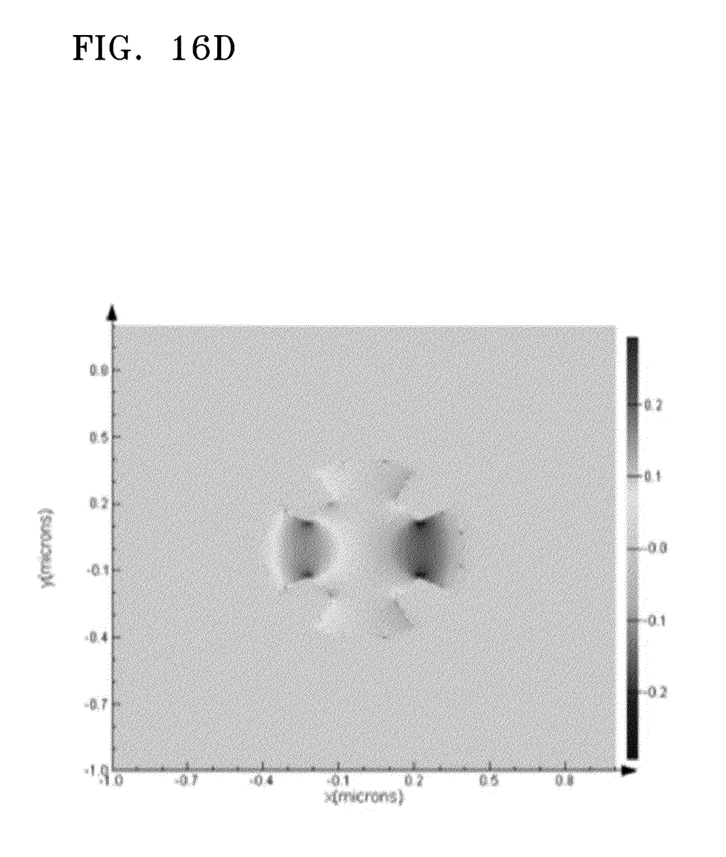

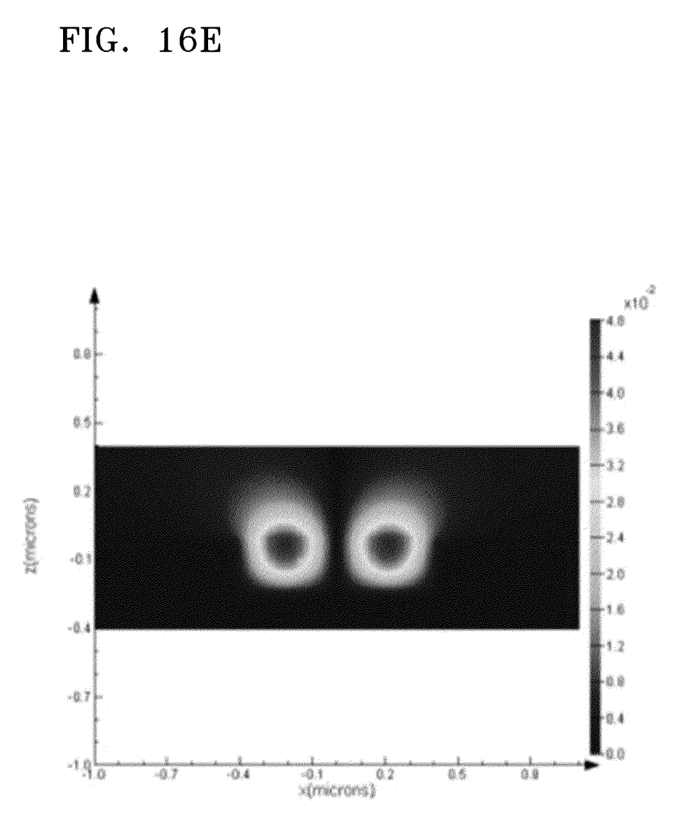

FIG. 16A is a view of the gain medium layer 220 of FIGS. 12A and 12B, wherein Ag surrounds the gain medium layer 220 and silicon oxide (SiO₂) covers an upper portion of the gain medium layer 220. Since each portion of the gain medium layer 220 of FIG. 16A is described in detail above with reference to the gain medium layer 220 of FIGS. 12A and 12B, details thereof are not provided again. Also, FIGS. 16B through 16E illustrate intensity distributions of an electric field of a TE₂₁ mode laser beam generated by the gain medium layer 220 of FIG. 16A. Here, TEₘₙ mode denotes a transverse electric mode representing an electromagnetic field in a resonator when an electric field is generated perpendicular to a proceeding direction of electromagnetic waves. In a resonator including the gain medium layer 220 of FIG. 16A, electromagnetic waves are confined in the resonator but since some of the electromagnetic waves are coupled to an upper SiO2 layer and are discharged, a proceeding direction of an electromagnetic field may be assumed to be a z-axis. Accordingly, at this time, an electric field is generated on an x-y plane perpendicular to the z-axis in a TE resonant mode. According to an exemplary embodiment, m and n are each an integer and respectively denote a mode number of an azimuthal direction and a mode number of a radial direction. In detail, FIGS. 16B, 16C, and 16D illustrate intensity distributions of an electric field on an x-y plane, in an x-axis direction, and in a y-axis direction of the TE₂₁ mode laser beam generated by the gain medium layer 220 of FIG. 16A, and FIG. 16E illustrates intensity distributions of an electric field viewed from an z-x cross section. In FIGS. 16B through 16E, a red region denotes a region where intensity of an electric field is strong and a blue region denotes a region where intensity of an electric field is weak. Also, FIG. 16F illustrates a spectrum of the TE₂₁ mode laser beam generated by the gain medium layer 220 of FIG. 16A. FIGS. 16B through 16F illustrate results obtained via simulation when the gain medium layer 220 of FIGS. 12A and 12B having the four protrusions 220b is formed of InP and has the outer radius r1, the inner radius r2, the thickness t, the angle θ1 of the protrusion 220b, and the angle θ2 of the recessed portion 220c respectively of 400 nm, 250 nm, 235 nm, 60°, and 30°, lower and upper portions of the gain medium layer 220 are respectively covered by Ag and SiO₂, and an electric dipole is set in a y-axis direction. Referring to FIGS. 16B through 16F, only one TE₂₁ like resonant mode of about 2.410 μm wavelength is generated. Accordingly, the laser beam generated by the gain medium layer 220 may be designed to have a desired wavelength and a desired resonant mode.

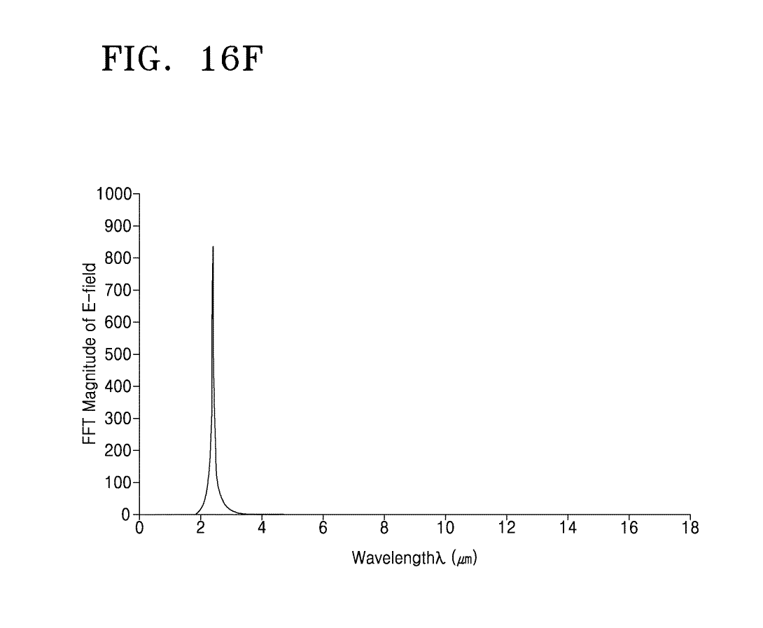

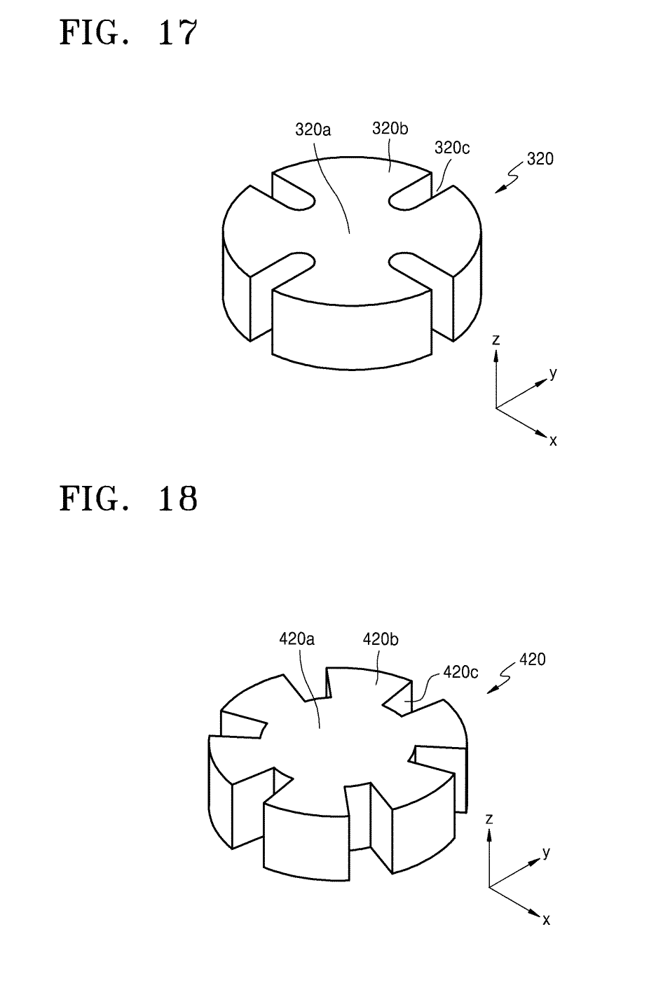

FIG. 17 is a perspective view of a gain medium layer according to another exemplary embodiment.

Referring to FIG. 17, the gain medium layer 320 includes a central portion 320a and a plurality of protrusions 320b around the central portion 320a. The protrusions 320b may be arranged in a periodic structure around the central portion 320a, and a plurality of recessed portions 320c may be formed between the protrusions 320b at regular intervals from each other. The central portion 320a may have, for example, a circular plane shape, but is not limited thereto. In FIG. 17, four protrusions 320b are provided around the central portion 320a. The recessed portions 320c between the protrusions 320b may have a uniform width along a radius direction of the gain medium layer 320.

FIG. 18 is a perspective view of a gain medium layer 420 according to another exemplary embodiment.

Referring to FIG. 18, six protrusions 420b having the same shape are provided around the central portion 420a in a periodic structure, wherein a plurality of recessed portions 420c are formed between the protrusions 420b at regular intervals from each other. The number of protrusions 420b arranged around the central portion 420a may vary. For example, an even number of protrusions 420b may be provided around the central portion 420a. In this case, when the result of dividing the number of protrusions 420b by 2 is an even number, even resonant modes (for example, TM₂₁, TE₂₁, or TM₄₁) may be generated, and when the result of dividing the number of protrusions 420b by 2 is an odd number, odd resonant modes (for example, TM₃₁ or TE₃₁) may be generated.

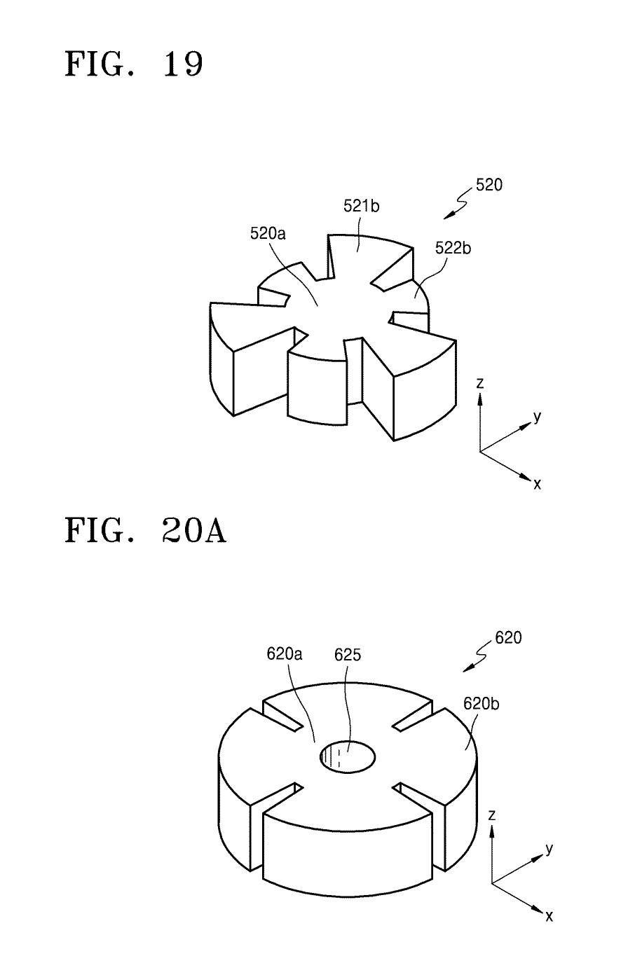

FIG. 19 is a perspective view of a gain medium layer according to another exemplary embodiment.

Referring to FIG. 19, at least one first protrusion 521b and at least one second protrusion 522b are arranged around a central portion 520a of the gain medium layer 520 in a periodic structure. In FIG. 19, three first protrusions 521b and three second protrusions 522b are arranged around the central portion 520a. Here, the first protrusion 521b and the second protrusion 522b may have different shapes, and may be alternately arranged around the central portion 520a. The shapes, sizes, or numbers of the first and second protrusions 521b and 522b may vary. When the protrusions 520b include the first and second protrusions 521b and 522b having different shapes as such, resonant modes may be effectively separated.

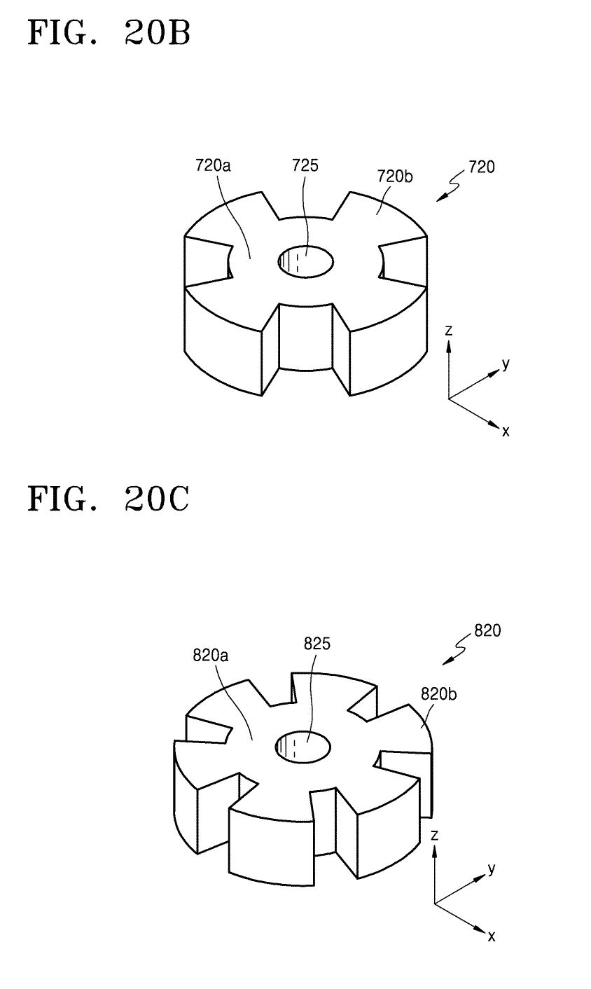

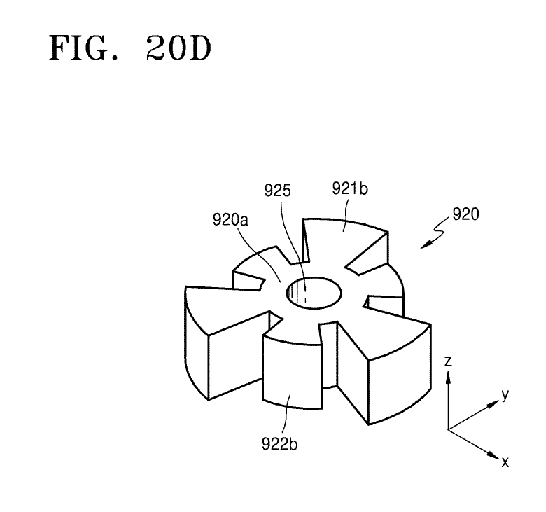

FIGS. 20A through 20D are perspective views of gain medium layers through according to other exemplary embodiments.

Referring to FIGS. 20A and 20B, pluralities of protrusions 620b and 720b are periodically arranged around central portions 620a and 720a of the gain medium layers 620 and 720, respectively, wherein through holes 625 and 725 are formed in the central portions 620a and 720a of the gain medium layers 620 and 720, respectively. In FIGS. 20A and 20B, the through holes 625 and 725 have a circular shape, but alternatively, the through holes 625 and 725 may have any shape, such as a quadrangular shape. Also, the sizes or numbers of the through holes 625 and 725 may vary. Referring to FIG. 20C, six protrusions 820b having the same shape are arranged around a central portion 820a of the gain medium layer 820, wherein a through hole 825 is formed in the central portion 820a of the gain medium layer 820. Referring to FIG. 20D, six protrusions 920b are arranged around a central portion 920a of the gain medium layer 920, wherein a through hole 925 is formed in the central portion 920a of the gain medium layer 920. The protrusions 920b include three first protrusions 921b and three second protrusions 922b, wherein the first and second protrusions 921b and 922b have different shapes and are alternately arranged. Also, the shapes, sizes, or numbers of the first and second protrusions 921b and 922b may vary. As shown in FIGS. 20A through 20D, by forming the through holes 625 through 925 in the central portions 620a through 920a of the gain medium layers 620 through 920, a desired resonant wavelength may be easily selected.

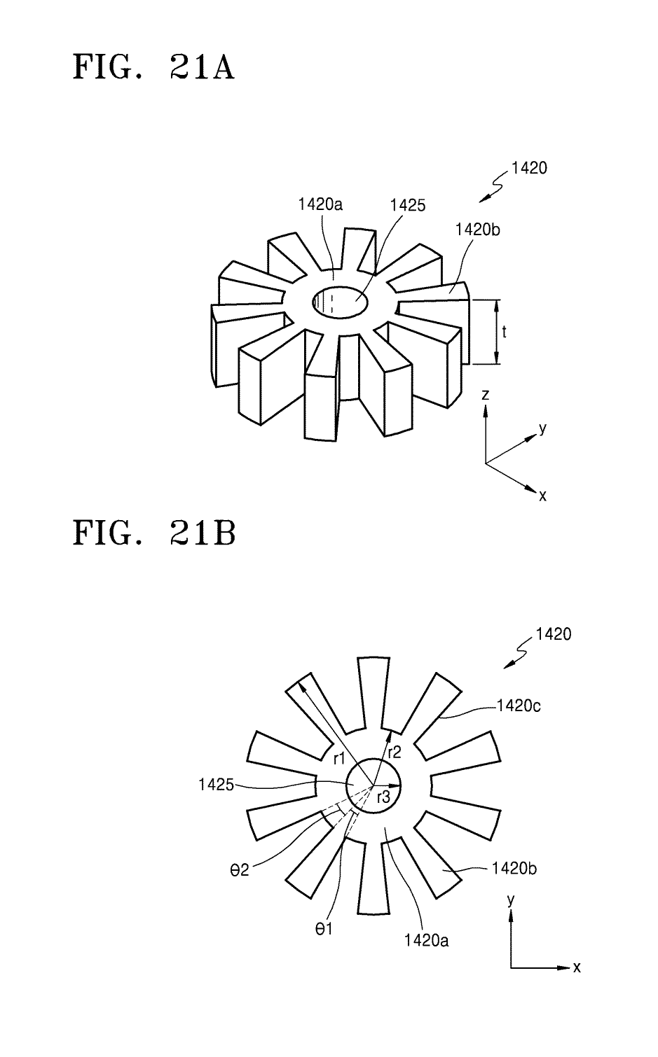

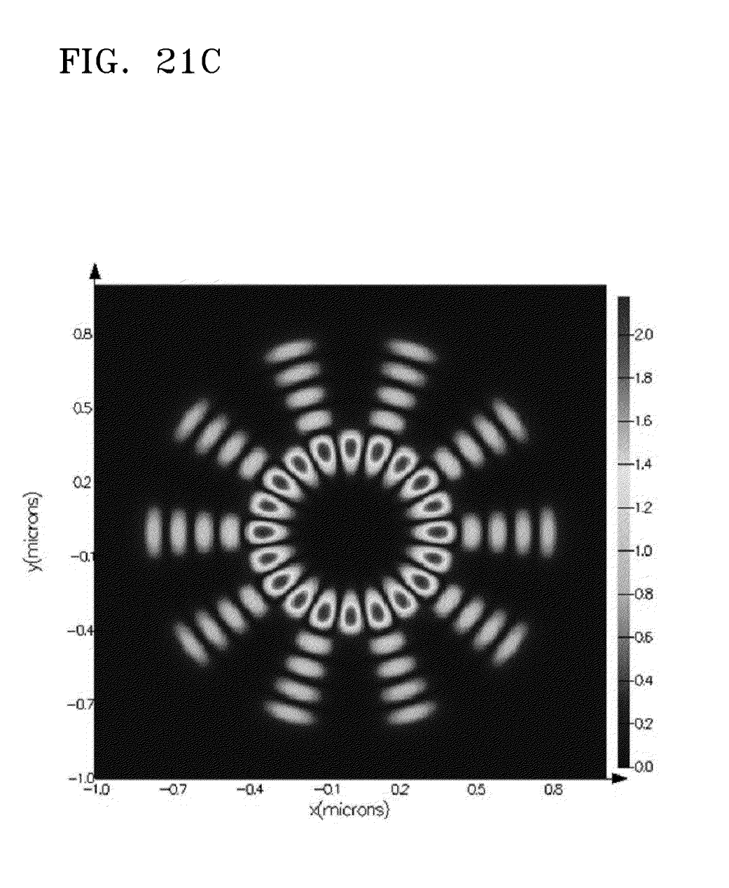

FIGS. 21A and 21B are respectively a perspective view and a plan view of a gain medium layer according to another exemplary embodiment. Referring to FIGS. 21A and 21B, ten protrusions 1420b are periodically arranged around a central portion 1420a of the gain medium layer 1420, wherein a through hole 1425 is formed in the central portion 1420a of the gain medium layer 1420.

FIG. 21C illustrates intensity distributions of an electric field of a laser beam generated by the gain medium layer 1420 of FIGS. 21A and 21B. In FIG. 21C, a red region denotes a region where intensity of an electric field is strong and a blue region denotes a region where intensity of an electric field is weak. FIG. 21C illustrates results obtained via simulation when the gain medium layer 1420 of FIGS. 21A and 21B having the ten protrusions 1420b is formed of InGaAs having a refractive index n of 3.55, has an outer radius r1, an inner radius r2, a radius r3 of the through hole 1425, a thickness t, an angle θ1 of the protrusion 1420b, and an angle θ2 of a recessed portion 1420c respectively of 800 nm, 400 nm, 200 nm, 1100 nm, 18°, and 18°, and is surrounded by Ag, and an electric dipole is set in a z-axis direction. Referring to FIG. 21C, a laser beam having a TM_{10,5} resonant mode of 0.65 μm wavelength and generated by the gain medium layer 1420 is confined as standing waves in the protrusions 1420b. The laser beam may also be confined in the central portion 1420a of the gain medium layer 1420.

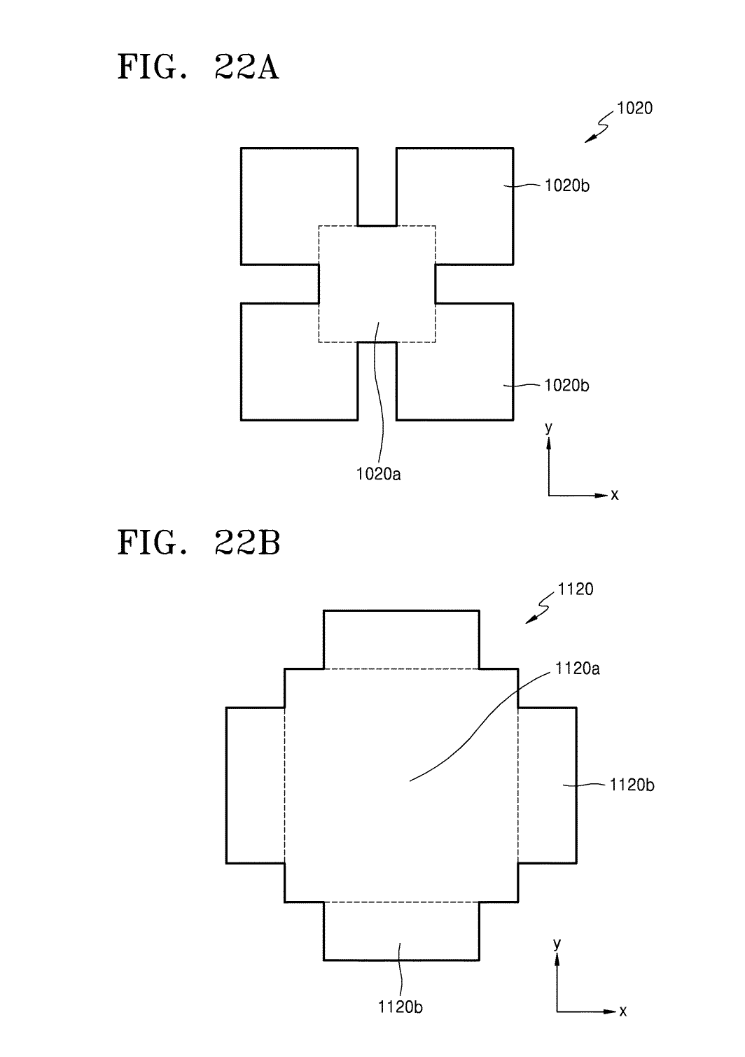

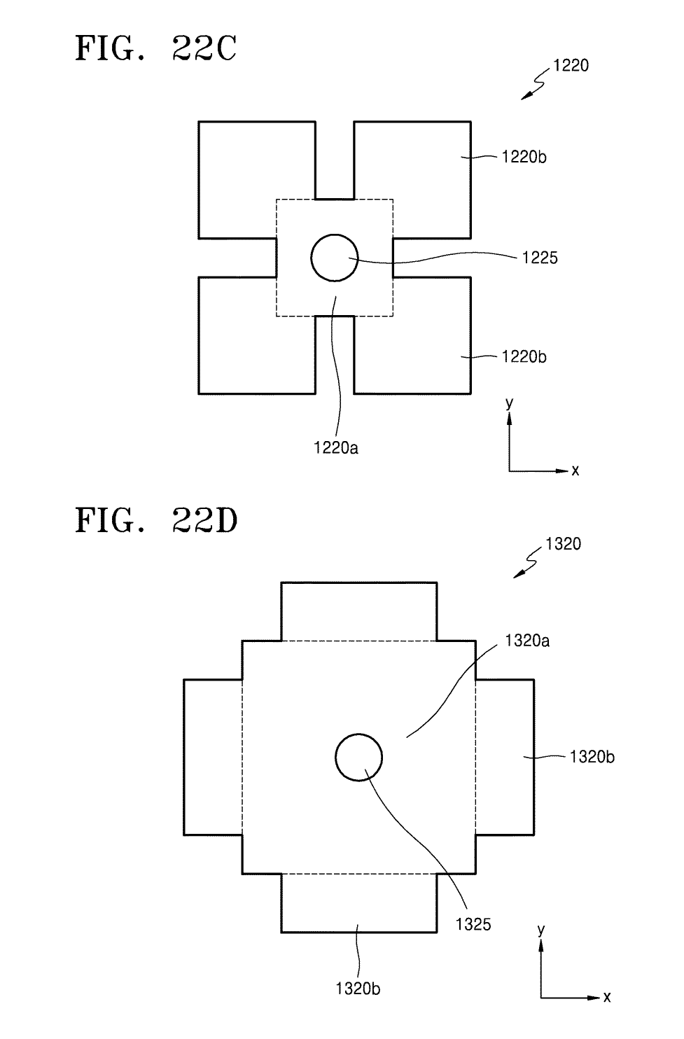

FIGS. 22A through 22D illustrate gain medium layers according to other exemplary embodiments.

Referring to FIGS. 22A and 22B, the gain medium layers 1020 and 1120 include central portions 1020a and 1120a having quadrangular plane shapes, and pluralities of protrusions 1020b and 1120b that are periodically arranged around the central portions 1020a and 1120a. The protrusions 1020b and 1120b may have, for example, square or rectangular plane shapes, or may have any other plane shape. Referring to FIGS. 22C and 22D, pluralities of protrusions 1220b and 1320b are periodically arranged around central portions 1220a and 1320a of the gain medium layers 1220 and 1320, respectively, wherein through holes 1225 and 1325 are formed in the central portions 1220a and 1320a of the gain medium layers 1220 and 1320, respectively. The through holes 1225 and 1325 may have circular shapes, or any other shapes, such as quadrangular shapes. Also, the sizes or numbers of the through holes 1225 and 1325 may vary.

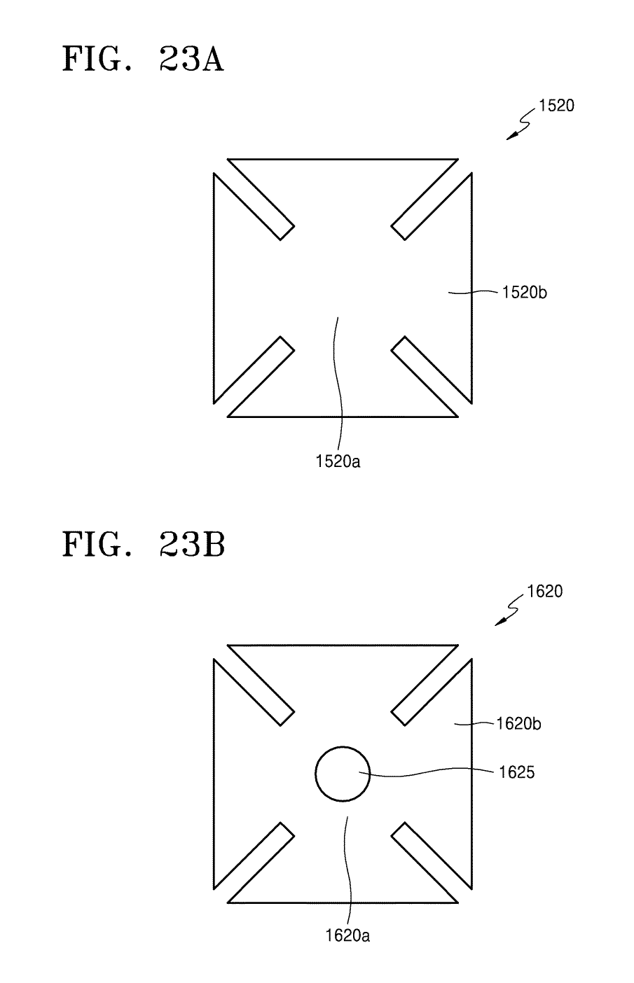

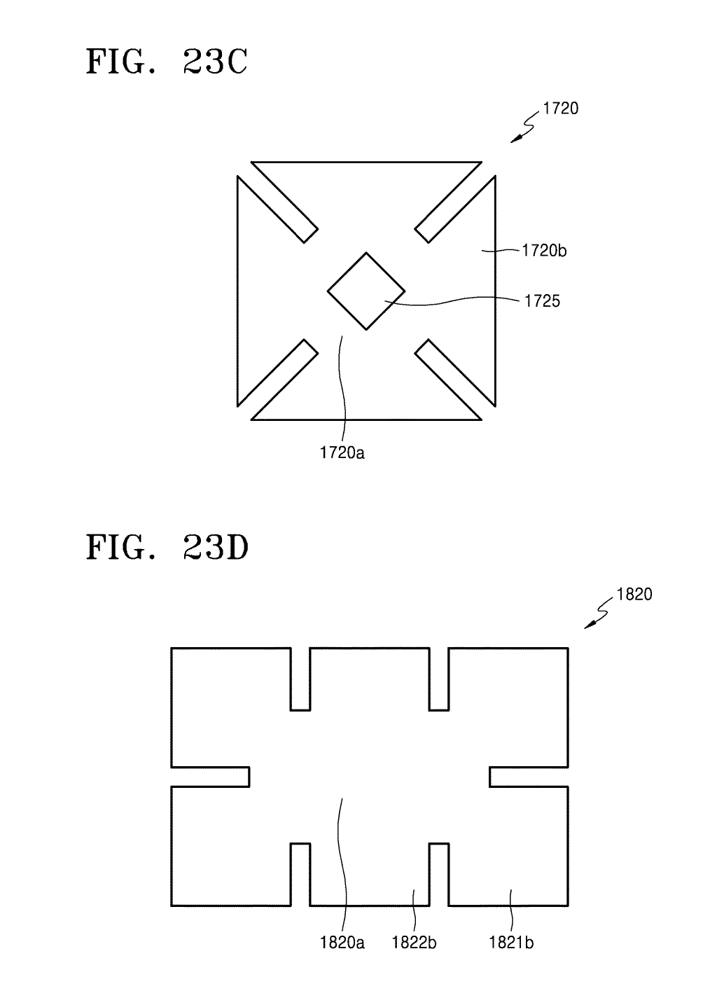

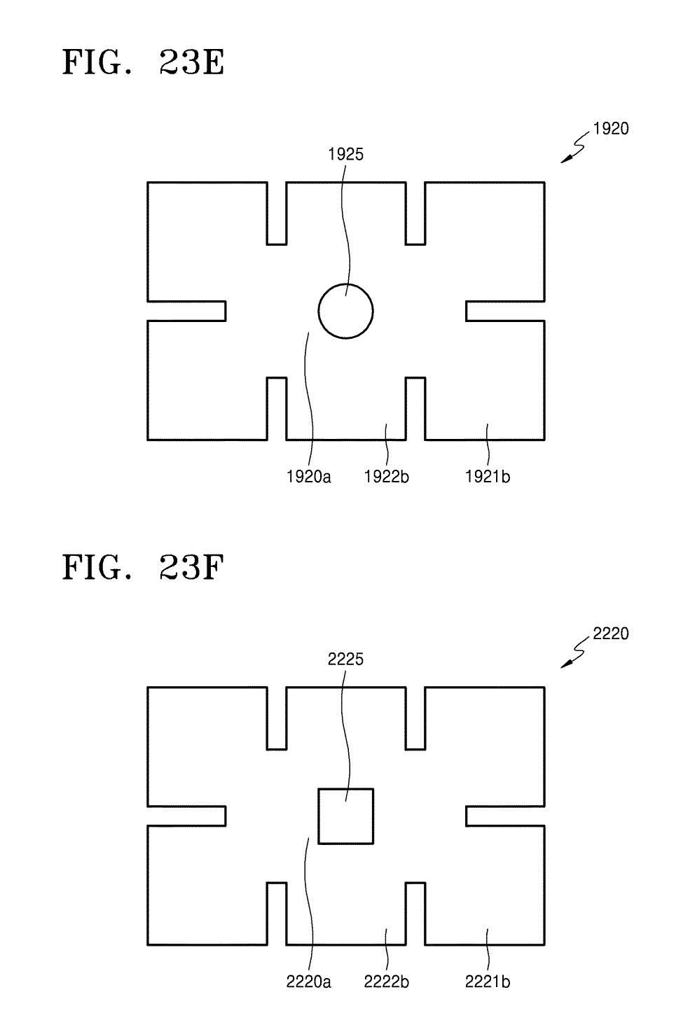

FIGS. 23A through 23F illustrate gain medium layers according to other exemplary embodiments.

Referring to FIGS. 23A through 23C, four protrusions 1520b through 1720b are provided around central portions 1520a through 1720a of the gain medium layers 1520 through 1720, and recessed portions between the protrusions 1520b through 1720b are formed in diagonal directions of the gain medium layers 1520 through 1720. In FIG. 23B, a circular through hole 1620 is formed in the central portion 1620a, and in FIG. 23C, a square through hole 1725 is formed in the central portion 1720a.

Referring to FIGS. 23D through 23F, central portions 1820a, 1920a, and 2220a of the gain medium layers 1820, 1920, and 2220 have rectangular plane shapes, and the six protrusions are periodically arranged around the central portions 1820a, 1920a, and 2220a. Here, the six protrusions include four first protrusions 1821b, 1921b, and 2221b, and two second protrusions 1822b, 1922b, and 2222b. In FIG. 23E, a circular through hole 1925 is formed in the central portion 1920a, and in FIG. 23F, a square through hole 2225 is formed in the central portion 2220a.

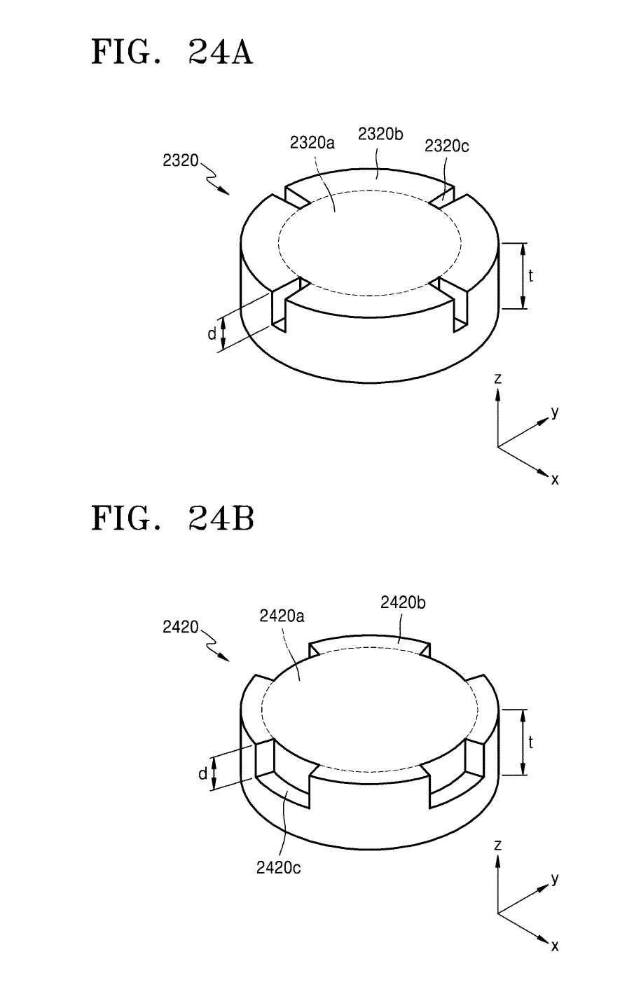

FIGS. 24A and 24B illustrate gain medium layers 2320 and 2420 according to other exemplary embodiments.

Referring to FIGS. 24A and 24B, pluralities of protrusions 2320b and 2420b are periodically arranged around central portions 2320a and 2420a of the gain medium layers 2320 and 2420, respectively, wherein recessed portions 2320c and 2420c are formed between the pluralities of protrusions 2320b and 2420b at regular intervals, respectively. Here, the recessed portions 2320c and 2420c are formed only at parts of the gain medium layers 2320 and 2420 along a thickness direction, e.g., in a z-axis direction. In other words, the recessed portions 2320c and 2420c may be formed by depths d from top surfaces of the gain medium layers 2320 and 2420. For example, the depths d of the recessed portions 2320c and 2420c may be halves of thicknesses t of the gain medium layers 2320 and 2420. Alternatively, the depths d of the recessed portions 2320c and 2420c may vary. Meanwhile, bottoms of the recessed portions 2320c and 2420c may protrude to surfaces of the protrusions 2320b and 2420b.

Even when the recessed portions 2320c and 2420c between the protrusions 2320b and 2420b of the gain medium layers 2320 and 2420 are formed only at the parts of the gain medium layers 2320 and 2420 in the thickness direction as such, laser beams generated by the gain medium layers 2320 and 2420 may be confined as standing waves in at least one of the protrusions 2320b and 2420b. Also, the gain medium layers 2320 and 2420 may be manufactured via simple processes since the recessed portions 2320c and 2420c are formed by removing top surfaces of the gain medium layers 2320 and 2420 by a certain depth via etching.

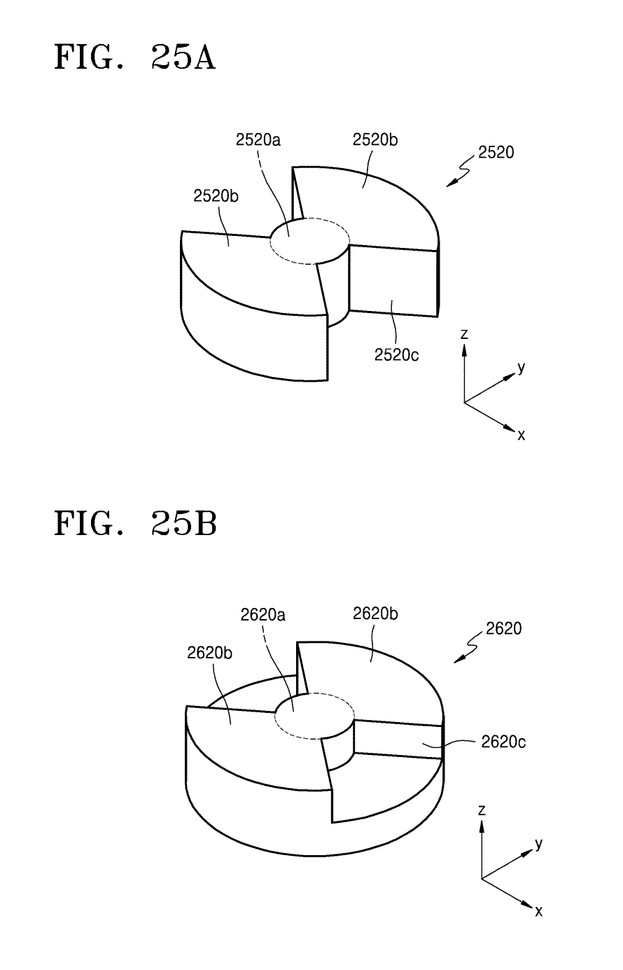

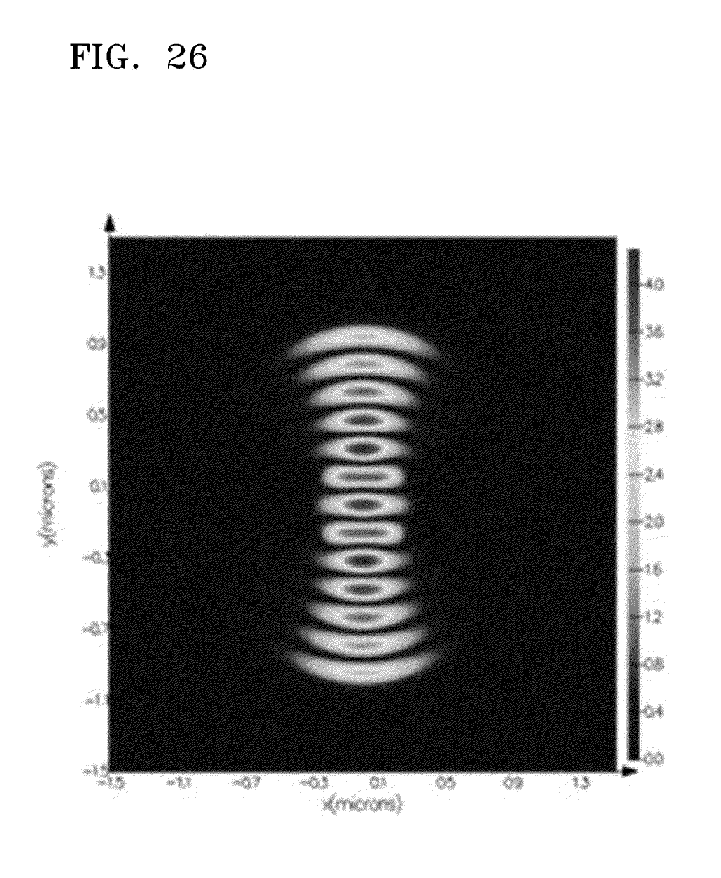

FIGS. 25A and 25B illustrate gain medium layers 2520 and 2620 according to other exemplary embodiments. In the gain medium layers 2520 and 2620 of FIGS. 25A and 25B, two protrusions 2520b and 2620b are arranged around central portions 2520a and 2620a, respectively, wherein two recessed portions 2520c and 2620c are formed between the protrusions 2520b and 2620b, respectively. Meanwhile, in the gain medium layer 2620 of FIG. 25B, the recessed portions 2620c are formed only at a part of the gain medium layer 2620 in a thickness direction, e.g., in a z-axis direction. FIG. 26 illustrates intensity distributions of an electric field of a laser beam generated by the gain medium layer 2520 of FIG. 25A.

According to the above exemplary embodiments, by arranging protrusions in a periodic structure around a central portion of a gain medium layer, a laser beam generated by the gain medium layer may be confined as standing waves in at least one of the protrusions. As such, undesired resonant modes may be removed or a desired resonant mode may be effectively separated from other resonant modes. Thus, a Q-factor of a laser resonator may be improved, and the laser resonator may operate in a desired resonant mode of a desired wavelength. In addition, intensity of the desired resonant mode may be selectively reinforced. Since only the desired resonant mode is easily selected as such, a low threshold current may be realized. A resonant mode may be selected and/or separated based on a number, shape, or size of the protrusions that are periodically arranged around the central portion, based on an interval between the protrusions, or based on a size, shape, or number of through holes formed in the central portion. Also, by providing a metal layer outside the gain medium layer or a dielectric layer having a refractive index different from the gain medium layer, the laser beam generated by the gain medium layer may be efficiently confined.

As such, a semiconductor laser resonator capable of easily controlling a resonant mode may be applied to various fields. For example, an optical source may be realized as a nano-laser resonator so as to manufacture a super-speed, low-power, and miniaturized on-chip photonic integrated circuit (IC). When the nano-laser resonator is used as an optical signal transmitting unit, data may be transmitted at a high speed, and an optical through-silicon via (TSV) capable of transmitting a signal at a high speed and preventing heat emission may be realized. In addition, the nano-laser resonator may be applied as a highly precise and high-speed optical clock source that is compatible with a complementary metal-oxide semiconductor (CMOS).

While one or more exemplary embodiments have been described with reference to the figures, it will be understood by those of ordinary skill in the art that various changes in form and details may be made therein without departing from the spirit and scope as defined by the following claims.

What is claimed is:

1. A semiconductor laser resonator configured to generate a laser beam, the semiconductor laser resonator comprising:
a gain medium layer including a semiconductor material and comprising:
a central portion; and
protrusions periodically arranged around the central portion,
wherein one of the protrusions is configured to confine the laser beam as a standing wave in the one protrusion.

2. The semiconductor laser resonator of claim 1, further comprising a metal layer provided outside the gain medium layer, the metal layer being configured to confine the laser beam generated by the gain medium layer.

3. The semiconductor laser resonator of claim 2, further comprising a buffer layer provided between the gain medium layer and the metal layer, the buffer layer being configured to buffer an optical loss of the laser beam generated by the gain medium layer.

4. The semiconductor laser resonator of claim 1, further comprising a dielectric layer provided outside the gain medium layer, the dielectric layer being configured to confine the laser beam generated by the gain medium layer and having a refractive index different from a refractive index of the gain medium layer.

5. The semiconductor laser resonator of claim 1, wherein the central portion is configured to further confine the laser beam therein.

6. The semiconductor laser resonator of claim 1, wherein the protrusions have a same shape as each other.

7. The semiconductor laser resonator of claim 1, wherein the protrusions comprise:
first protrusions each respectively having a first shape; and
second protrusions each respectively having a second shape different from the first shape.

8. The semiconductor laser resonator of claim 7, wherein the first and second protrusions are alternately arranged around the central portion.

9. The semiconductor laser resonator of claim 1, wherein the central portion has a circular or quadrangular plane shape.

10. The semiconductor laser resonator of claim 1, further comprising a through hole in the central portion.

11. The semiconductor layer resonator of claim 1, further comprising recessed portions formed between the protrusions at regular intervals from each other.

12. The semiconductor layer resonator of claim 11, wherein the recessed portions are formed only at a part of the gain medium layer along a thickness direction of the gain medium layer.

13. The semiconductor layer resonator of claim 11, wherein a number of the protrusions is from 2 to 10, and an angle between two sides of one of the protrusions, the two sides extending from a center of the gain medium layer to an outer circumference of the gain medium layer, is from 5° to 175°.

14. The semiconductor layer resonator of claim 13, wherein a thickness of the gain medium layer is less than or equal to 500 nm, an outer radius of the gain medium layer extending from the center of the gain medium layer to the outer circumference of the gain medium layer is from 100 nm to 5,000 nm, an inner radius of the gain medium layer extending from the center of the gain medium layer to an inner side of the recessed portions is from 100 nm to 4,000 nm, and a ratio of the inner radius to the outer radius is from 0.02 to 1.

15. The semiconductor laser resonator of claim 1, wherein the gain medium layer comprises an active layer.

16. The semiconductor laser resonator of claim 15, wherein the active layer comprises at least one of a III-V group semiconductor material, a II-VI group semiconductor material, and quantum dots.

17. The semiconductor laser resonator of claim 15, wherein the gain medium layer further comprises:
a first clad layer provided on a first surface of the active layer; and
a second clad layer provided on a second surface of the active layer.

18. The semiconductor laser resonator of claim 1, further comprising:
a first contact layer provided on a first surface of the gain medium layer; and
a second contact layer provided on a second surface of the gain medium layer.

19. The semiconductor laser resonator of claim 18, wherein the first contact layer and the second contact layer have a shape corresponding to a shape of the gain medium layer.

20. A semiconductor laser device comprising:
a substrate; and
a semiconductor laser resonator provided on the substrate and configured to generate a laser beam by absorbing energy, the semiconductor laser resonator comprising:
a gain medium layer including a semiconductor material and comprising:
a central portion; and
protrusions periodically arranged around the central portion,
wherein one of the protrusions is configured to confine the laser beam as a standing wave in the one protrusion.

21. The semiconductor laser device of claim 20, further comprising a metal layer provided outside the gain medium layer, the metal layer being configured to confine the laser beam generated by the gain medium layer.

22. The semiconductor laser device of claim 21, further comprising a buffer layer provided between the gain medium layer and the metal layer, the buffer layer being configured to buffer an optical loss of the laser beam generated by the gain medium layer.

23. The semiconductor laser device of claim 20, further comprising a dielectric layer provided outside the gain medium layer, the dielectric layer being configured to confine the laser beam generated by the gain medium layer, and having a refractive index different from a refractive index of the gain medium layer.

24. The semiconductor laser device of claim 20, wherein the central portion has a circular or quadrangular plane shape.

25. The semiconductor laser device of claim 20, further comprising a through hole in the central portion.

26. The semiconductor layer device of claim 20, further comprising recessed portions formed between the protrusions at regular intervals from each other.

27. The semiconductor layer device of claim 26, wherein the recessed portions are formed only at a part of the gain medium layer along a thickness direction of the gain medium layer.

28. The semiconductor laser device of claim 20, further comprising:
a first contact layer provided on a first surface of the gain medium layer; and
a second contact layer provided on a second surface of the gain medium layer.

29. The semiconductor laser device of claim 28, further comprising electrodes electrically connected to the first contact layer and the second contact layer.
